(19) United States
(12) Patent Application Publication
(10) Pub. No.: US 2024/0224517 A1
(43) Pub. Date: Jul. 4, 2024

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Yang Chen, Wuhan (CN); Di Wang, Wuhan (CN); Jingtao Xie, Wuhan (CN); Qingfu Zhang, Wuhan (CN); Zhiliang Xia, Wuhan (CN); Zongliang Huo, Wuhan (CN)

(21) Appl. No.: 18/093,199

(22) Filed: Jan. 4, 2023

(30) Foreign Application Priority Data
Dec. 30, 2022 (CN) 202211723777.1

(51) Int. Cl. H10B 43/27; H10B 41/27

(52) U.S. Cl. CPC H10B 43/27; H10B 41/27

(57) ABSTRACT

A method for forming a three-dimensional (3D) memory device is disclosed. A stack structure including interleaved first dielectric layers and second dielectric layers is formed. Channel structures extending through the first dielectric layers and the second dielectric layers in a first region of the stack structure are formed. All the second dielectric layers in the first region and parts of the second dielectric layers in a second region of the stack structure are replaced with conductive layers. Word line pick-up structures extending through the first dielectric layers and remainders of the second dielectric layers in the second region of the stack structure are formed at different depths. A portion of the second dielectric layers in the second region that is closest to the opening is converted into a dielectric material different from the material of the second dielectric layers.

### CROSS-REFERENCE TO RELATED APPLICATIONS

This application claims the benefit of priority to Chinese Application No. 202211723777.1, filed Dec. 30, 2022, which is incorporated herein by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a method for forming a 3D memory device is disclosed. A stack structure including interleaved first dielectric layers and second dielectric layers is formed. The first dielectric layers include a first dielectric material, and the second dielectric layers include a second dielectric material. Channel structures extending through the first dielectric layers and the second dielectric layers in a first region of the stack structure are formed. All the second dielectric layers in the first region and parts of the second dielectric layers in a second region of the stack structure are replaced with conductive layers. Word line pick-up structures extending through the first dielectric layers and remainders of the second dielectric layers in the second region of the stack structure are formed at different depths. Each word line pick-up structure extends along a sidewall of an opening in the second region. A portion of the second dielectric layers in the second region that is closest to the opening is converted into a third dielectric material different from the second dielectric material.

In some implementations, to form the word line pick-up structures, the openings extending through the first dielectric layers and the remainders of the second dielectric layers in the second region of the stack structure are formed at different depths. An interconnect line is formed at a bottom of each of the openings, and the interconnect lines are in contact with the conductive layers, respectively. Contact structures are formed in the openings in contact with the interconnect lines, respectively.

In some implementations, a filler is formed in each of the openings after forming the respective contact structure.

In some implementations, to form the word line pick-up structures, recesses are created in at least some of the remainders of the second dielectric layers exposed after forming the openings. The recesses are covered with the third dielectric material to form buffers.

In some implementations, after covering the recesses with the third dielectric material, the sidewalls of the openings are covered with a fourth dielectric material to form contact spacers.

In some implementations, the fourth dielectric material is the same as the third dielectric material.

In some implementations, to form the word line pick-up structures, the remainders of the second dielectric layers are oxidized to form buffers.

In some implementations, the buffers are formed by one of thermal oxidation or wet chemical oxidation.

In some implementations, to form the word line pick-up structures, the bottom of each of the openings is etched to expose part of the second dielectric layer, respectively. A respective portion of the exposed second dielectric layer in each of the openings is removed before forming the interconnect line in the removed portion, respectively.

In some implementations, the bottom of each of the openings is etched by at least one of dry etching or wet etching.

In another aspect, a 3D memory device includes a first region of a stack structure including interleaved conductive layers and first dielectric layers, a second region of the stack structure including interleaved second dielectric layers and the first dielectric layers, and word line pick-up structures each extending along a sidewall of an opening into the second region of the stack structure. A buffer covering the sidewall is disposed between the second dielectric layers and the word line pick-up structure. A surface of the buffer has a plurality of bumps along a direction parallel to the sidewall.

In some implementations, a contact spacer is formed between the buffer and the word line pick-up structures.

In some implementations, the contact spacer and the buffer each include a dielectric material selected from a group consisting of silicon oxide, silicon oxynitride, and a mixture of silicon oxide and silicon oxynitride.

In some implementations, each of the word line pick-up structures includes an interconnect line at a bottom of the word line pick-up structures that is in contact with one of the conductive layers, a contact structure electrically coupled to the interconnect line, and a filler that fills a remaining portion of the opening.

In some implementations, each of the plurality of bumps laterally corresponds to one of the first dielectric layers in the second region of the stack structure.

In some implementations, the buffer is formed by thin film deposition.

In some implementations, each of the plurality of bumps laterally corresponds to one of the second dielectric layers in the second region of the stack structure.

In some implementations, the buffer is formed by oxidizing remainders of the second dielectric layers.

In some implementations, the thickness of dielectric layers near the bottom of the word line pick-up structure is smaller than that of dielectric layers near the top of the bottom of the word line pick-up structure.

In some implementations, the dielectric material includes a native oxide layer.

In some implementations, the sidewall of at least one of the openings has a sidewall shoulder.

In some implementations, the word line pick-up structures extend into the second region of the stack structure at different depths.

In another aspect, a system includes a 3D memory device configured to store data and a memory controller control the 3D memory device. The 3D memory device includes a first region of a stack structure including interleaved conductive layers and first dielectric layers, a second region of the stack structure including interleaved second dielectric layers and the first dielectric layers, and word line pick-up structures each extending along a sidewall of an opening into the second region of the stack structure. A buffer covering the sidewall is disposed between the second dielectric layers and the word line pick-up structure. A surface of the buffer has a plurality of bumps along a direction parallel to the sidewall.

In some implementations, the system further includes a host coupled to the memory controller and configured to send or receive the data.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a plan view of a 3D memory device having word line pick-up structures, according to some aspects of the present disclosure.

FIG. 2 illustrates a top perspective view of a 3D memory device having word line pick-up structures, according to some aspects of the present disclosure.

FIG. 3 illustrates an enlarged top perspective view of a 3D memory device having word line pick-up structures, according to some aspects of the present disclosure.

FIG. 4 illustrates a cross-sectional side view of a 3D memory device having word line pick-up structures, according to some aspects of the present disclosure.

FIG. 5A illustrates a cross-sectional side view of a 3D memory device having word line pick-up structures, according to some aspects of the present disclosure.

FIG. 5B illustrates an enlarged view of a portion of the cross-sectional side view of the 3D memory device shown in FIG. 5A, according to some aspects of the present disclosure.

FIG. 6A illustrates a cross-sectional side view of another 3D memory device having word line pick-up structures, according to some aspects of the present disclosure.

FIG. 6B illustrates an enlarged view of a portion of the cross-sectional side view of the 3D memory device shown in FIG. 6A, according to some aspects of the present disclosure.

FIGS. 7A-7H illustrate a fabrication process for forming a 3D memory device having word line pick-up structures, according to some aspects of the present disclosure.

FIGS. 8A-8G illustrate a fabrication process for forming another 3D memory device having word line pick-up structures, according to some aspects of the present disclosure.

FIG. 9 is a flowchart of a method for forming a 3D memory device having word line pick-up structures, according to some aspects of the present disclosure.

FIG. 10 illustrates a block diagram of an exemplary system having a 3D memory device, according to some aspects of the present disclosure.

FIG. 11A illustrates a diagram of an exemplary memory card having a 3D memory device, according to some aspects of the present disclosure.

FIG. 11B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical contacts are formed) and one or more dielectric layers.

In some 3D memory devices, such as 3D NAND memory devices, memory cells for storing data are vertically stacked through a stack structure (e.g., a memory stack) in vertical channel structures. 3D memory devices usually include staircase structures formed on one or more sides (edges), or at the center, of the stacked storage structure for purposes such as word line pick-up/fan-out using word line contacts landed onto different steps/levels of a staircase structure. Dummy channel structures are usually formed through the memory stack in regions outside of the core array region in which the channel structures of 3D NAND memory devices are formed, such as staircase regions having the staircase structures, to provide mechanical support to the stack structure, in particular, during the gate replacement process that temporarily removes some layers of the stack structure through slit openings across the core array region and staircase regions of the stack structure.

The integration of the various structures, such as dummy channel structures, word line contacts, staircase structures, slit openings, etc., from both the device design perspective and the fabrication process perspective, has become more and more challenging as the memory cell density of the 3D NAND memory devices continues increasing.

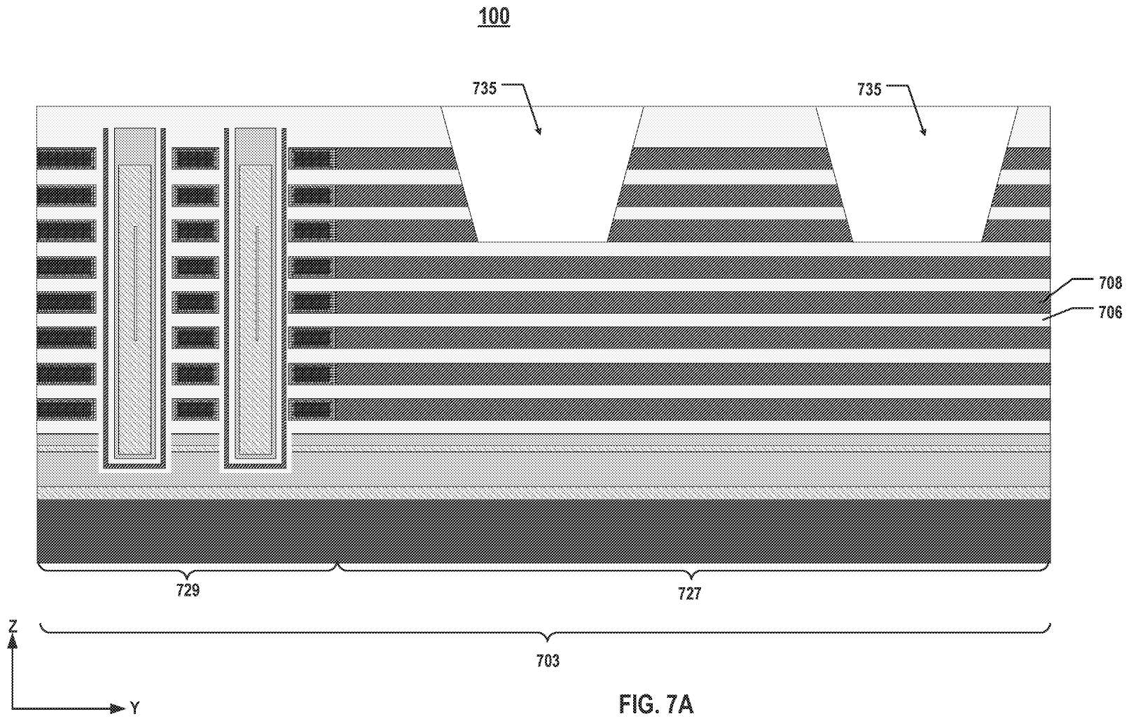

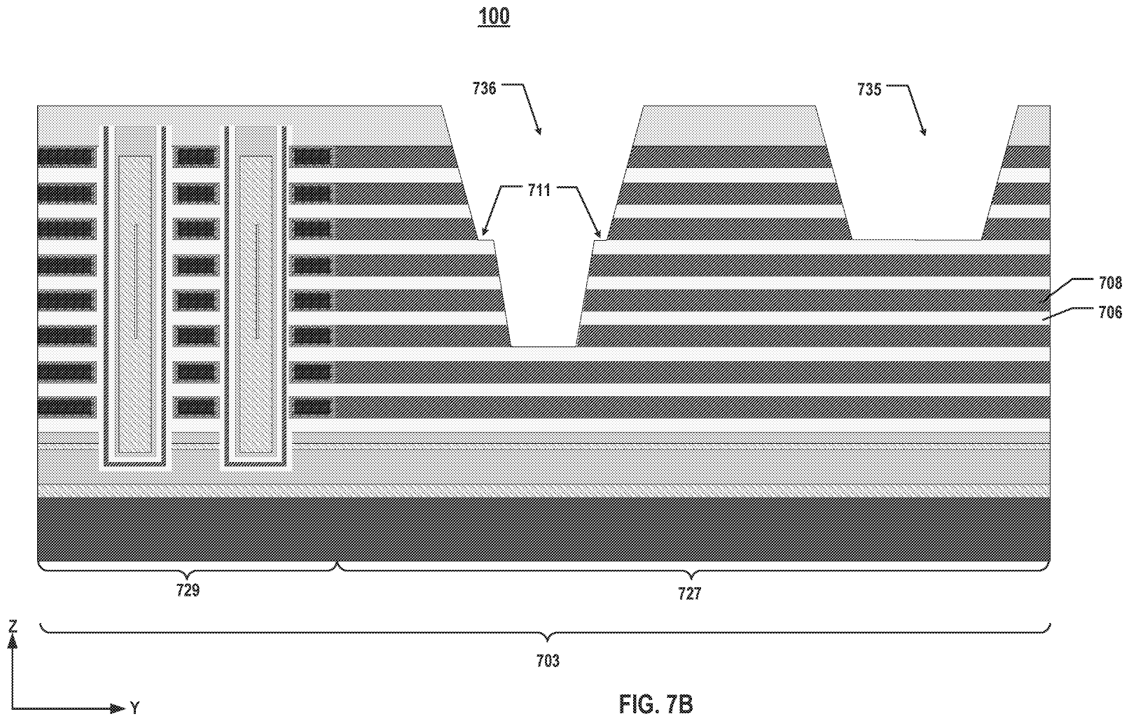

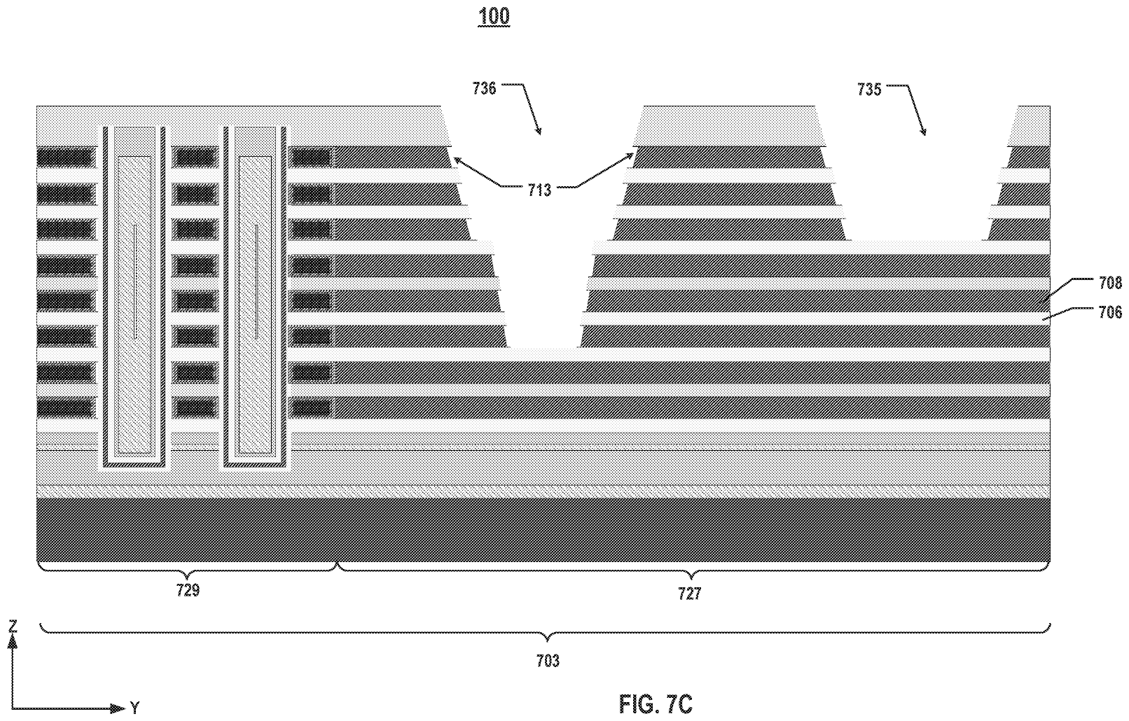

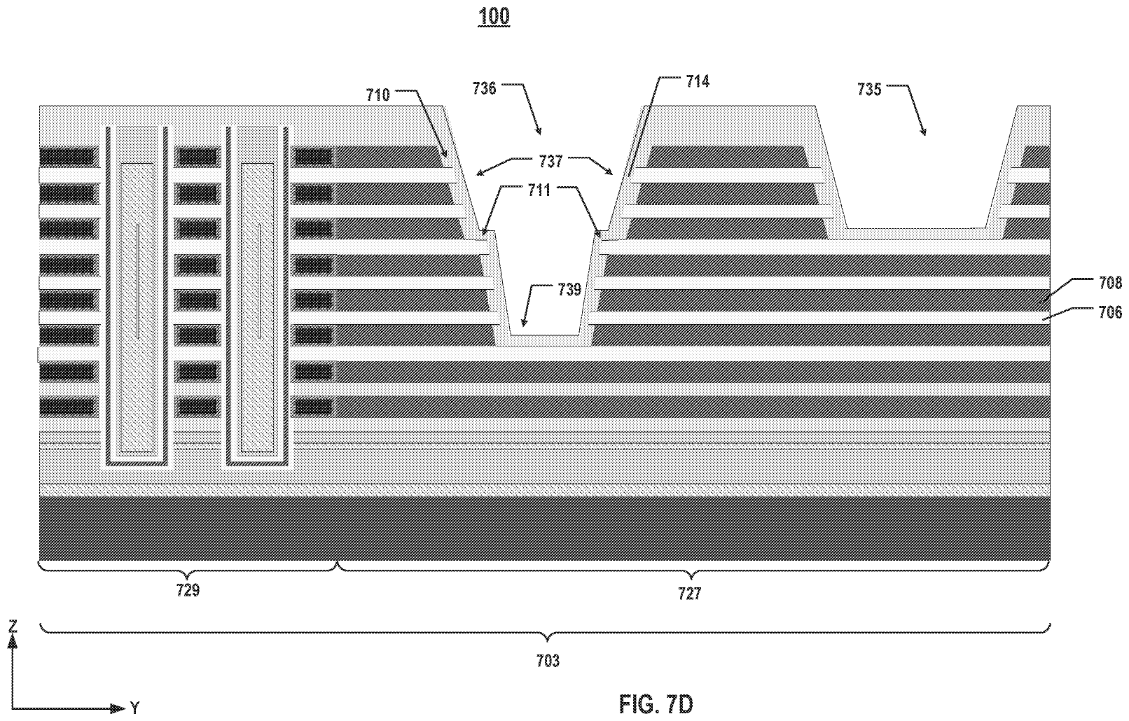

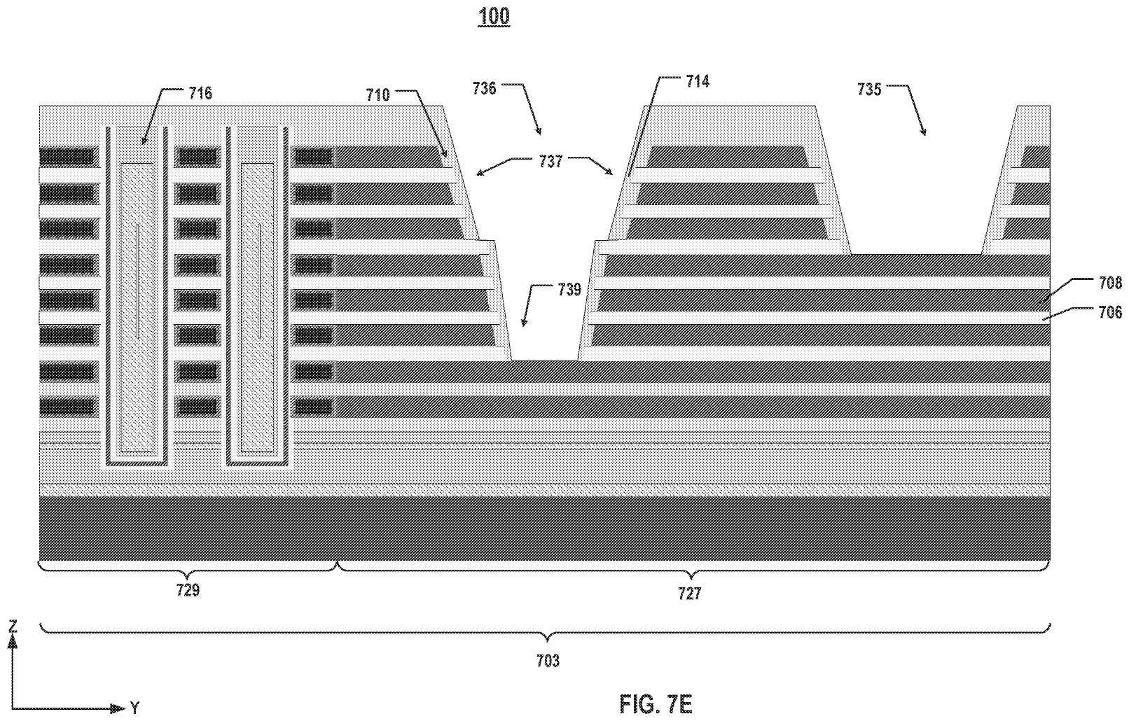

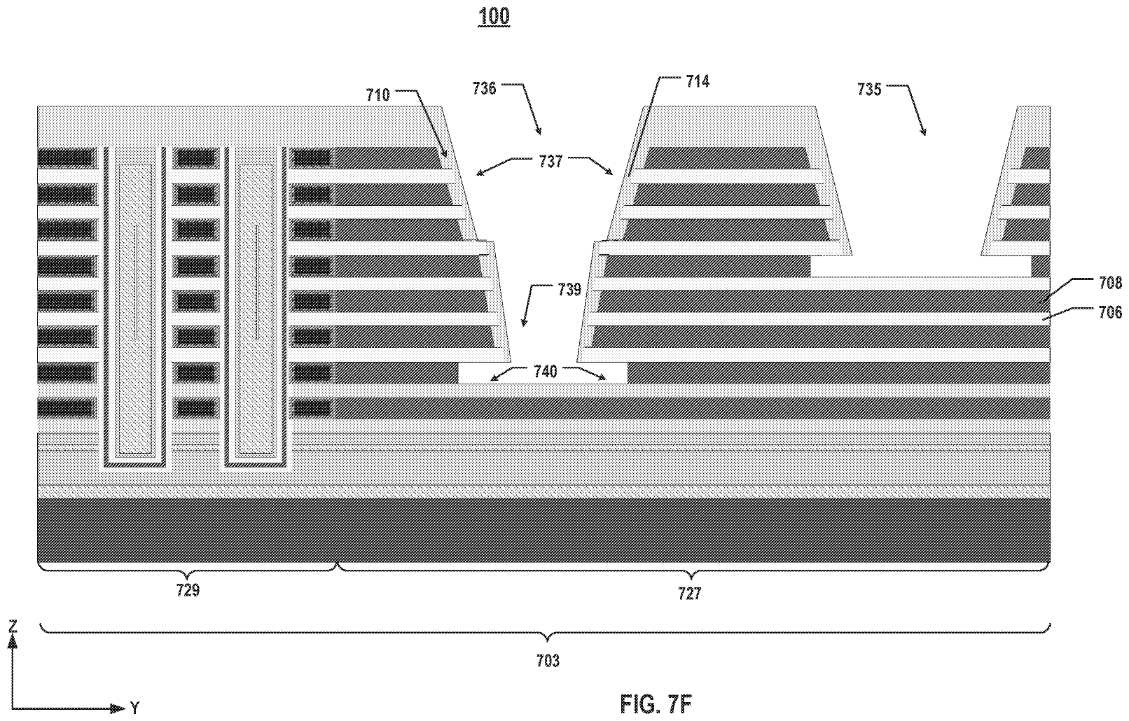

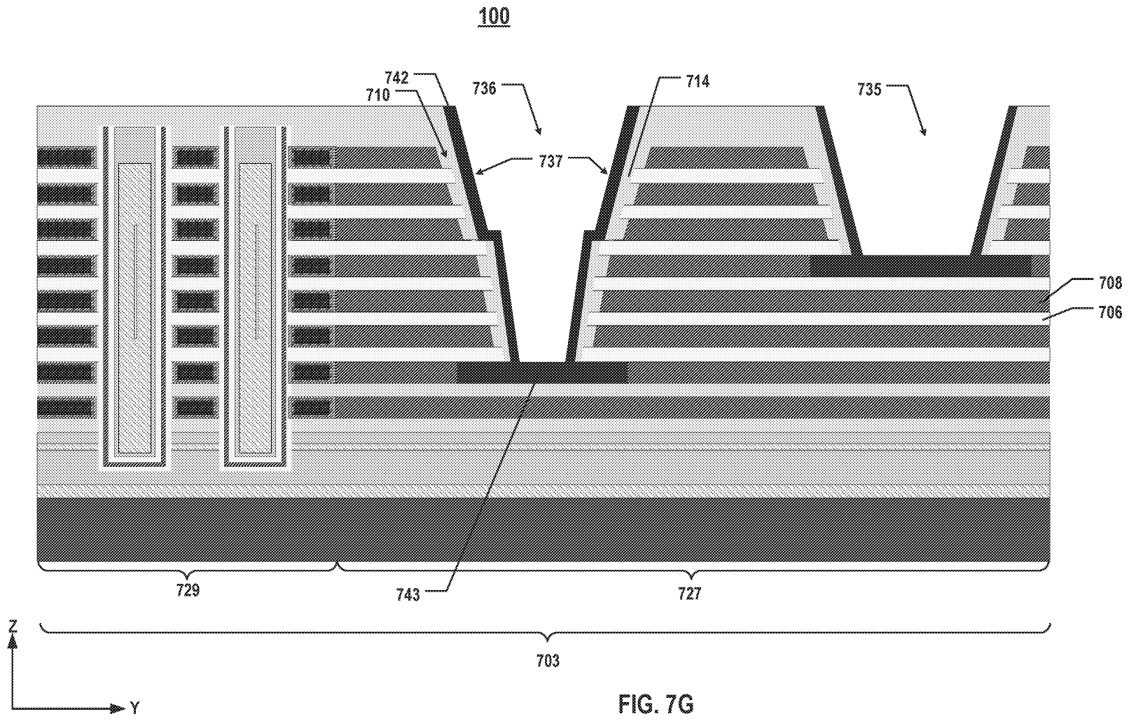

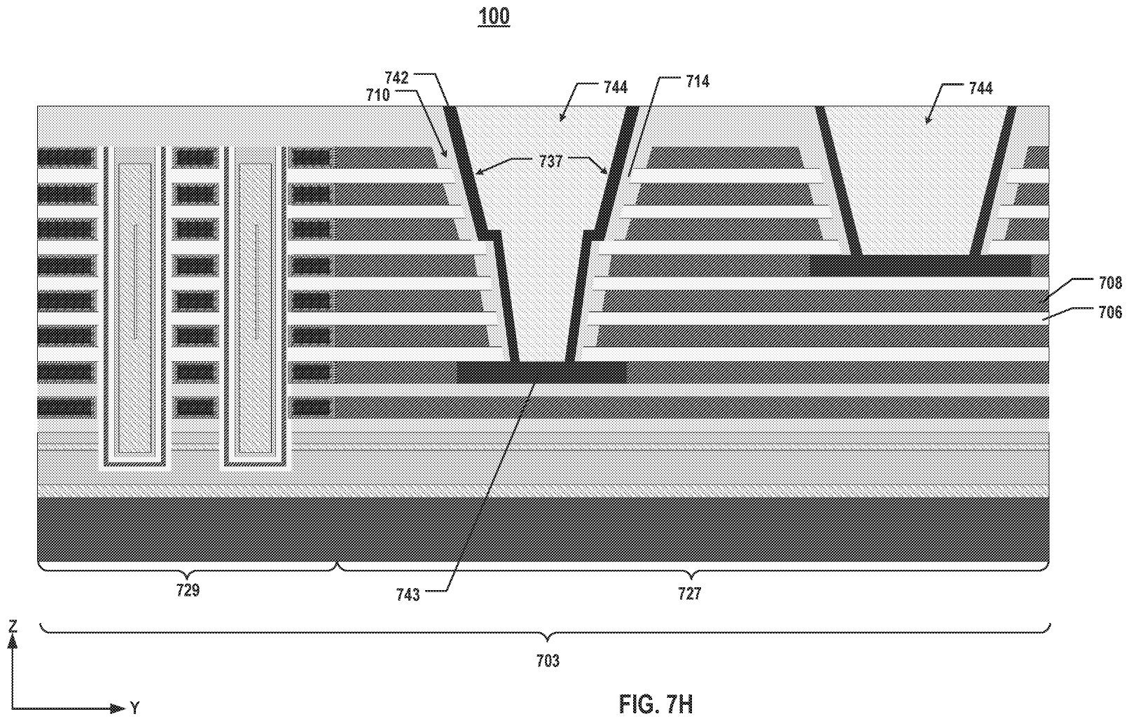

Moreover, during the formation of word line pick-up structures, openings are formed in the word line pick-up region. The openings extend vertically into the stack structure. The openings are formed using a chopping process, which employs a plurality of masks so that the openings can reach different depths inside the stack structure. However, sidewall shoulders (such as sidewall shoulders 711 in FIG. 7B) are easy to be created in the openings as a result of multiple times of etching with masks having a gap or overlay therebetween. Such shoulders may leave the dielectric layers abutting the shoulder area in the sidewall of the opening vulnerable to be exposed after etching. Thus, when the silicon nitride on the bottom of the openings is removed and replaced with conductive material to form an interconnect line, the exposed dielectric layers abutting the sidewall are also removed and replaced with the same conductive material. This replacement of dielectric layers on the sidewall may cause word line leakage and deterioration of the performance of the 3D NAND memory devices.

To address one or more of the aforementioned issues, the present disclosure introduces a solution that protects the dielectric layers abutting the shoulder area from being exposed after etching. In particular, a buffer is formed between at least some of the dielectric layers and the sidewall of the opening. In some implementations, a contact spacer may be additionally formed by covering the sidewall of the opening with a dielectric material. The buffer can have the same dielectric material as the contact spacer. The buffer can be formed by creating lateral recesses in the dielectric layers, followed by depositing the dielectric material into the lateral recesses. Alternatively, the buffer can be formed by oxidizing the dielectric layers. As a result, the thickness of the buffer is large enough to protect the dielectric layers from being exposed in the openings due to subsequent etching and being replaced by conductive layers. Compared with the existing technology, the 3D memory devices according to the present disclosure reduce or prevent leakage current in the word line pick-up structures, thereby enhancing the performance of the 3D memory devices.

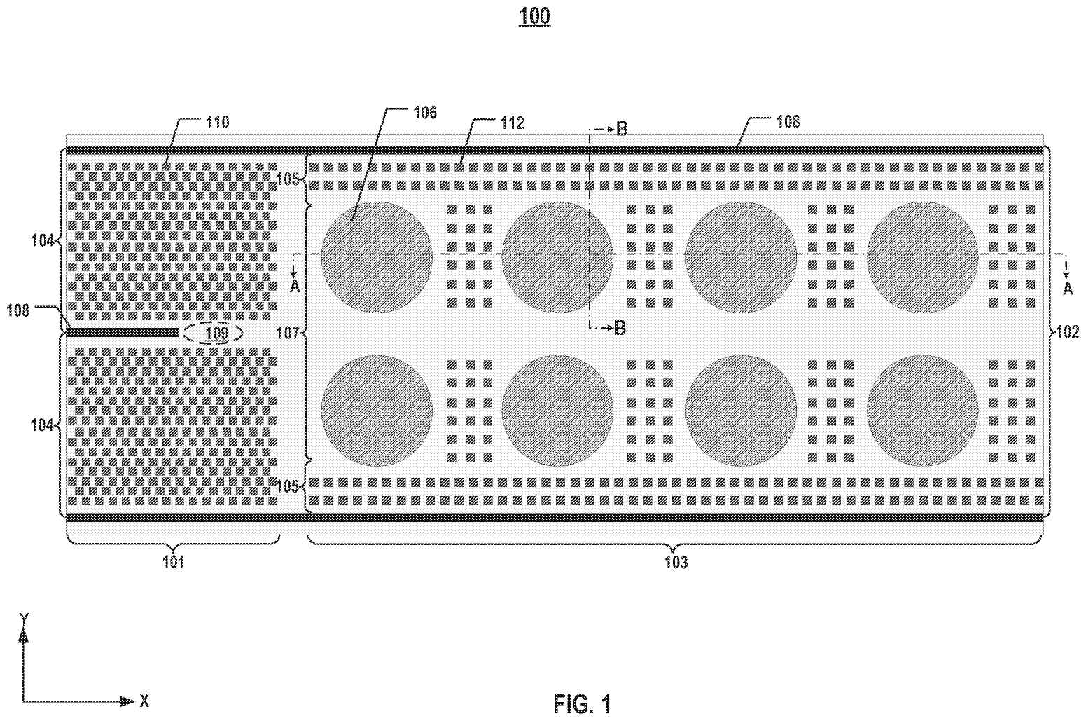

FIG. 1 illustrates a plan view of a 3D memory device 100 having word line pick-up structures 106, according to some aspects of the present disclosure. In some implementations, 3D memory device 100 is a NAND Flash memory device in which memory cells are provided in the form of an array of NAND memory strings. It is noted that x and y axes are included in FIG. 1 to illustrate two orthogonal (perpendicular) directions in the wafer plane. The x-direction is the word line direction of 3D memory device 100, and the y-direction is the bit line direction of 3D memory device 100.

As shown in FIG. 1, 3D memory device 100 can include one or more blocks 102 arranged in the y-direction (the bit line direction) separated by parallel slit structures 108, such as gate line slits (GLSs). In some implementations in which 3D memory device 100 is a NAND Flash memory device, each block 102 is the smallest erasable unit of the NAND Flash memory device. Each block 102 can further include multiple fingers 104 in the y-direction separated by some of slit structures 108 with “H” cuts 109.

As shown in FIG. 1, 3D memory device 100 can be divided into at least a core array region 101 in which an array of channel structures 110 are formed, as well as a word line pick-up region 103 in which word line pick-up structures 106 are formed. Core array region 101 and word line pick-up region 103 are arranged in the x-direction (the word line direction), according to some implementations. It is understood that although one core array region 101 and one word line pick-up region 103 are illustrated in FIG. 1, multiple core array regions 101 and/or multiple word line pick-up regions 103 may be included in 3D memory device 100, for example, one word line pick-up region 103 between two core array regions 101 in the x-direction, in other examples. It is also understood that FIG. 1 only illustrates portions of core array region 101 that are adjacent to word line pick-up region 103.

As described below in detail, word line pick-up region 103 can include conductive portions 105 and dielectric portions 107 arranged in the y-direction. As shown in FIG. 1, word line pick-up structures 106 are disposed in dielectric portion 107, while dummy channel structures 112 are disposed in conductive portion 105 of word line pick-up region 103 to provide mechanical support and/or load balancing, according to some implementations. In some implementations (e.g., as shown in FIG. 1), dummy channel structures 112 are disposed in dielectric portion 107 of word line pick-up region 103 as well, for example, between word line pick-up structures 106 in the x-direction. In some implementations, dummy channel structures 112 are not disposed in dielectric portion 107 of word line pick-up region 103, i.e., only in conductive portion 105 of word line pick-up region 103. As shown in FIG. 1, each finger 104 of 3D memory device 100 can include one row of word line pick-up structures 106 disposed in dielectric portion 107 of word line pick-up region 103. It is understood that the layout and arrangement of word line pick-up structures 106, as well as the shape of each word line pick-up structure 106, may vary in different examples.

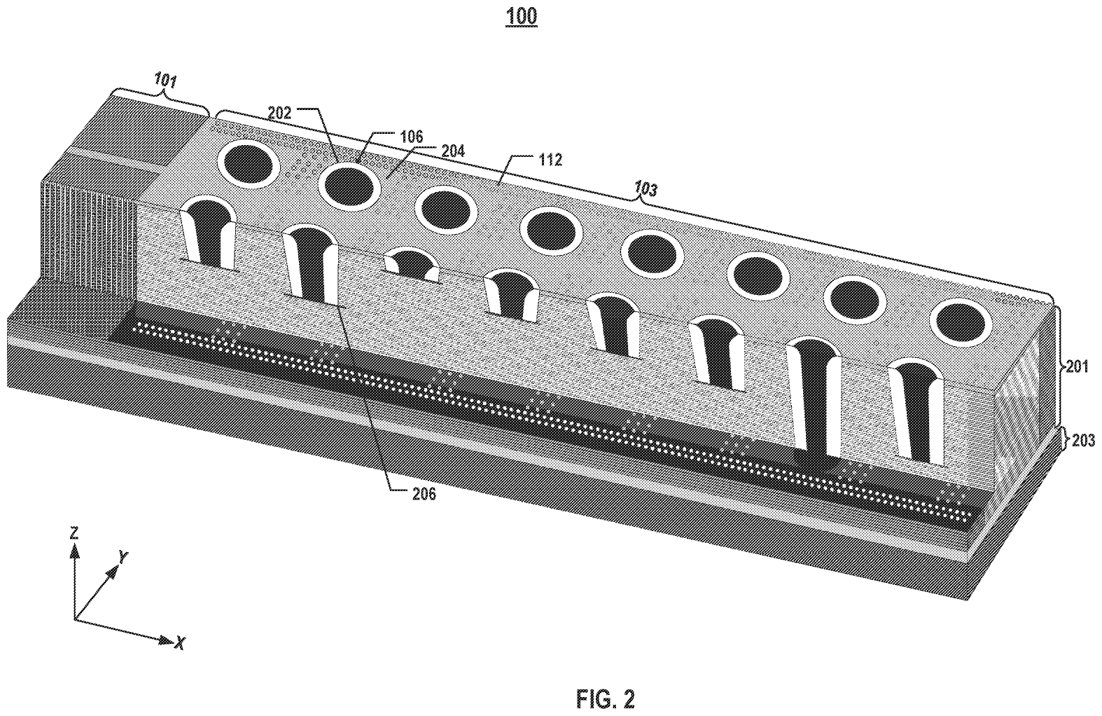

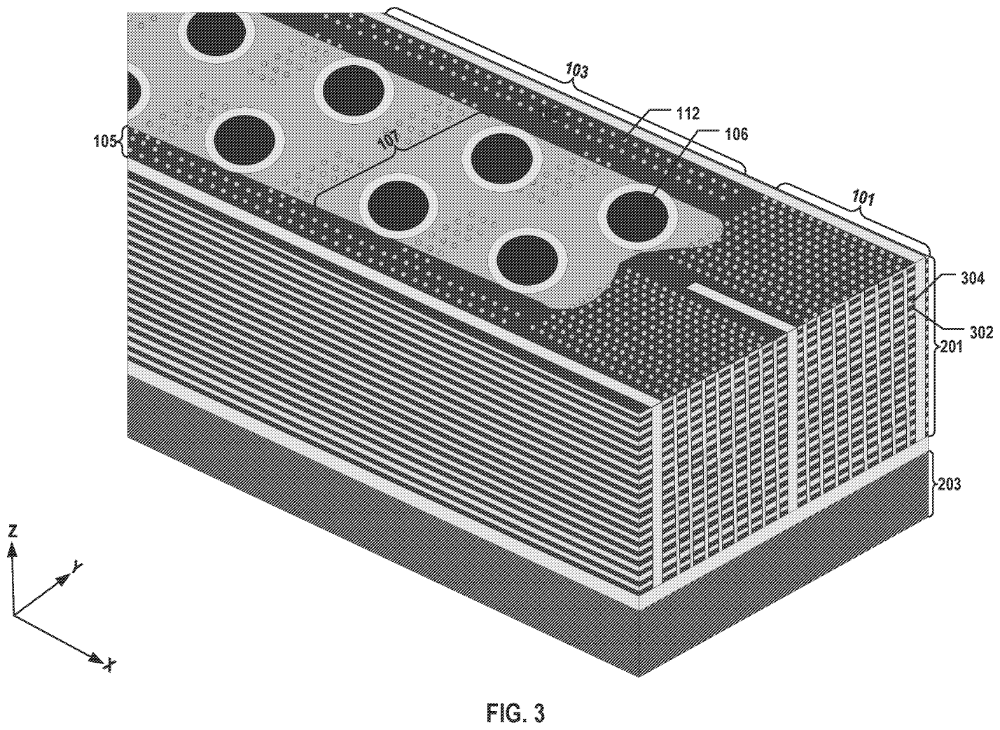

FIG. 2 illustrates a top perspective view of 3D memory device 100 having word line pick-up structures 106, according to some aspects of the present disclosure. FIG. 3 illustrates an enlarged top perspective view of 3D memory device 100 having word line pick-up structures 106, according to some aspects of the present disclosure. As shown in FIGS. 2 and 3, a stack structure 201 can be formed on a substrate 203, which can include silicon (e.g., single crystalline silicon), silicon germanium (SiGe), gallium arsenide (GaAs), germanium (Ge), silicon on insulator (SOI), or any other suitable materials. In some implementations, substrate 203 includes single crystalline silicon, which is part of the wafer on which 3D memory device 100 is fabricated, either in its native thickness or being thinned. In some implementations, substrate 203 includes, for example, polysilicon, which is a semiconductor layer replacing the part of wafer on which 3D memory device 100 is fabricated. It is noted that x, y, and z axes are included in FIGS. 2 and 3 to further illustrate the spatial relationship of the components in 3D memory device 100. Substrate 203 of 3D memory device 100 includes two lateral surfaces extending laterally in the x-y plane: a top surface on the front side of the wafer on which stack structure 201 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 100 is determined relative to substrate 203 of 3D memory device 100 in the z-direction (the vertical direction perpendicular to the x-y plane) when substrate 203 is positioned in the lowest plane of 3D memory device 100 in the z-direction. The same notion for describing the spatial relationship is applied throughout the present disclosure.

As shown in FIG. 3, stack structure 201 can include vertically interleaved first material layers 302 and second material layers 304 that are different from first material layers 302. First material layers 302 and second material layers 304 can alternate in the vertical direction (the z-direction). In some implementations, stack structure 201 can include a plurality of material layer pairs stacked vertically in the z-direction, each of which includes a first material layer 302 and a second material layer 304. The number of the material layer pairs in stack structure 201 can determine the number of memory cells in 3D memory device 100.

In some implementations, 3D memory device 100 is a NAND Flash memory device, and stack structure 201 is a stacked storage structure through which NAND memory strings are formed. As shown in FIG. 3, second material layers 304 can have different materials in different regions/portions of 3D memory device 100. Thus, stack structure 201 may be viewed as having a number of stack structures with different materials of second material layers 304 for ease of description in the present disclosure. In some implementations, core array region 101 and conductive portion 105 of word line pick-up region 103 include a conductive stack structure having interleaved conductive layers and first dielectric layers. That is, second material layers 304 of stack structure 201 may be conductive layers in core array region 101 and conductive portion 105 of word line pick-up region 103. In some implementations, dielectric portion 107 of word line pick-up region 103 includes a dielectric stack structure having interleaved second dielectric layers and the first dielectric layers. That is, second material layers 304 of stack structure 201 may be the second dielectric layers in dielectric portion 107 of word line pick-up region 103. First material layers 302 of stack structure may be the same—the first dielectric layers—in the conductive stack structure and the dielectric stack structure across core array region 101 and word line pick-up region 103. As described below in detail with respect to the fabrication process, the formation of stack structure 201 with different materials of second material layer 304 in different regions/portions can be achieved by controlling the different degrees and scopes of the gate replacement process in different regions/portions. For example, stack structure 201 may have undergone a complete gate replacement process in core array region 101 to replace all the second dielectric layers with the conductive layers, but a partial gate replacement process in word line pick-up region 103 to replace some of the second dielectric layers with the conductive layers in conductive portion 105, leaving the remainders of the second dielectric layers in dielectric portion 107.

In some implementations, each conductive layer in the conductive stack structure in core array region 101 and conductive portion 105 of word line pick-up region 103 functions as a gate line of the NAND memory strings (in the forms of channel structures 110) in core array region 101, as well as a word line extending laterally from the gate line and ending in conductive portion 105 of word line pick-up region 103 for word line pick-up/fan-out through word line pick-up structures 106. The word lines (i.e., the conductive layers) at different depths/level of the conductive stack structure each extends laterally in core array region 101 and conductive portion 105 of word line pick-up region 103, but are discontinuous (e.g., being replaced by the second dielectric layers) in dielectric portion 107 of word line pick-up region 103, according to some implementations.

The conductive layers can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. The dielectric layers can include dielectric materials including, but not limited to, silicon oxide, silicon nitride, silicon oxynitride, or any combination thereof. The first dielectric layers and the second dielectric layers can have different dielectric materials, such as silicon oxide and silicon nitride. In some implementations, the conductive layers include metals, such as tungsten, the first dielectric layers include silicon oxide, and the second dielectric layers include silicon nitride. For example, first material layers 302 of stack structure 201 may include silicon oxide across core array region 101 and word line pick-up region 103, and second material layers 304 of stack structure 201 may include tungsten in core array region 101 and conductive portion 105 of word line pick-up region 103 and silicon nitride in dielectric portion 107 of word line pick-up region 103.

As shown in FIGS. 2 and 3, the heights of stack structure 201 (e.g., the conductive stack structure and the dielectric stack structure) are uniform in core array region 101 and in word line pick-up region 103, according to some implementations. Different from some 3D memory devices that include one or more staircase structures in a staircase region (corresponding to word line pick-up region 103 for word line pick-up/fan-out), which has uniform heights of the stack structure in the staircase region, 3D memory device 100 can eliminate the staircase structures while still achieving the word line pick-up/fan-out function using word line pick-up structures 106, as described below in detail.

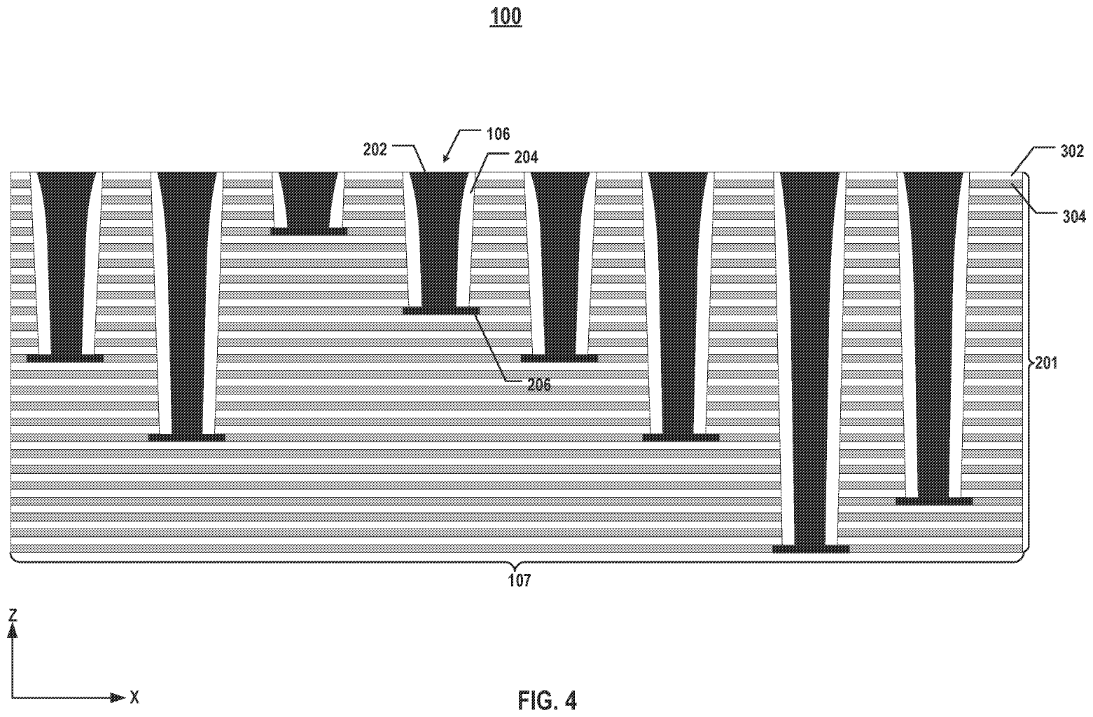

FIG. 4 illustrates a cross-sectional side view of 3D memory device 100 having word line pick-up structures 106, according to some aspects of the present disclosure. The cross-section may be along the AA direction in dielectric portion 107 of word line pick-up region 103 in FIG. 1. As shown in FIG. 4, word line pick-up structures 106 extend vertically into stack structure 201 (the dielectric stack structure in dielectric portion 107 of word line pick-up region 103) at different depths in the z-direction, according to some implementations. The top surfaces of different word line pick-up structures 106 can be flush with one another, while the bottom surfaces of different word line pick-up structures 106 can extend to different levels, for example, different second material layers 304 of stack structure 201.

In some implementations, word line pick-up structure 106 includes a contact structure 202, a contact spacer 204 circumscribing contact structure 202, and an interconnect line 206 below and in contact with contact structure 202. Contact structure 202 and interconnect line 206 can include conductive materials including, but not limited to, W, Co, Cu, Al, TiN, polysilicon, doped silicon, silicides, or any combination thereof. Contact spacer 204 can include dielectric materials including, but not limited to, silicon oxide, silicon nitride, silicon oxynitride, or any combination thereof. In some implementations, contact structure 202 and interconnect line 206 include TiN/W, and contact spacer 204 includes silicon oxide.

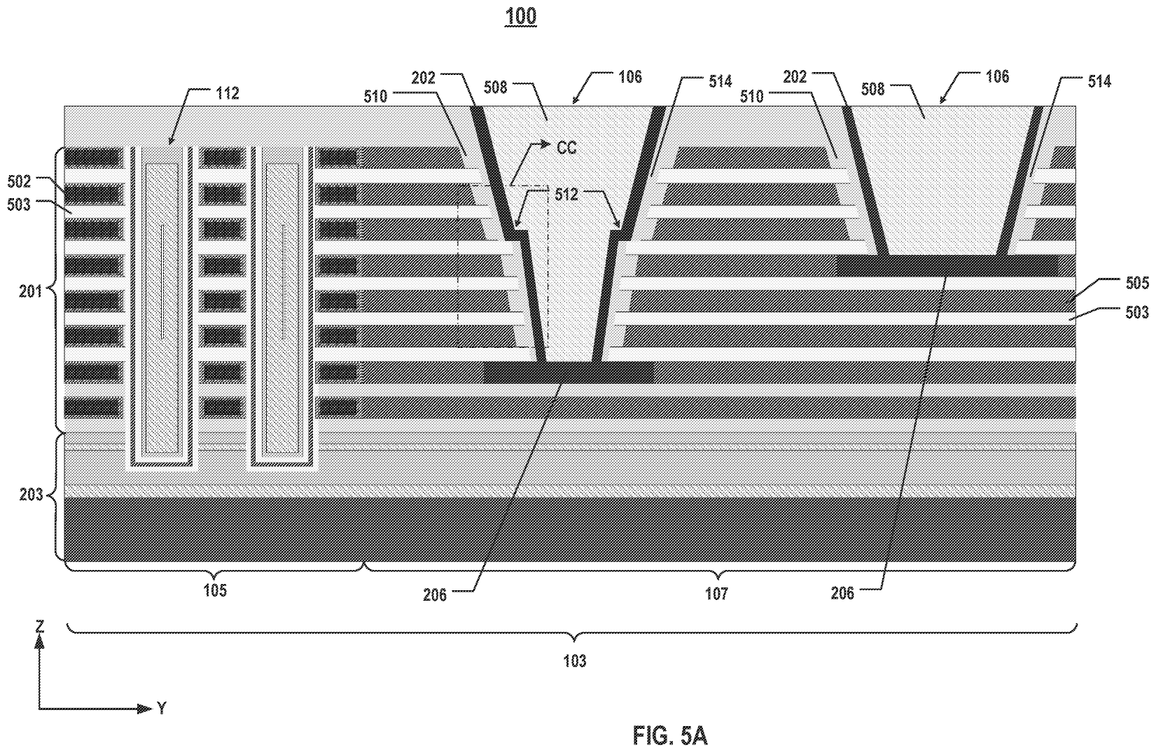

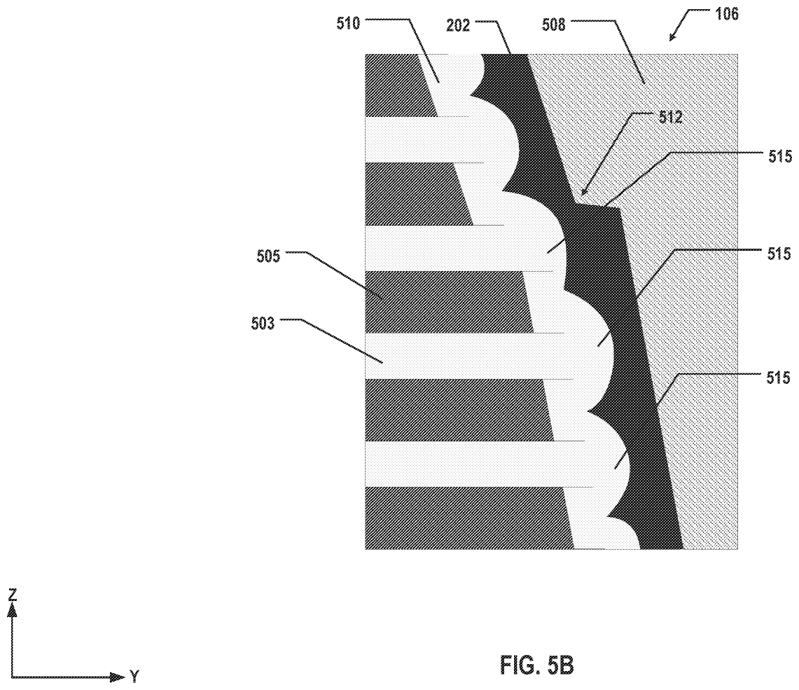

FIG. 5A illustrates a cross-sectional side view of 3D memory device 100 having word line pick-up structures 106, according to some aspects of the present disclosure. One cross-section may be along the BB direction in core array region 101 in FIG. 1. As shown in FIG. 5A, 3D memory device 100 can include dummy channel structures 112 in conductive portion 105 of word line pick-up region 103. Each dummy channel structure 112 can extend vertically through interleaved conductive layers 502 and first dielectric layers 503 of the conductive stack structure of stack structure 201 into substrate 203. In some implementations, 3D memory device 100 can further include slit structures (not shown in Figures) extending vertically through interleaved conductive layers 502 and first dielectric layers 503 of the conductive stack structure of stack structure 201 into substrate 203. The slit structures can be positioned between dummy channel structures 112, serving as insulating structures that separate conductive layers 502 (word lines) between different blocks 102.

Instead of having staircase structures and word line contacts landed on different levels/stairs of the staircase structures, 3D memory device 100 can include stack structure 201 with uniform heights and word line pick-up structures 106 in dielectric portion 107 of word line pick-up region 103 for word line pick-up/fan-out. As shown in FIG. 5A, interconnect line 206 of each word line pick-up structure 106 in dielectric portion 107 can extend laterally in the plane defined by x-direction and y-direction to be in contact with a corresponding conductive layer 502 (word line) in conductive portion 105 at the same level of stack structure 201. Since interconnect line 206 is in contact with contact structure 202 of word line pick-up structure 106, each word line pick-up structure 106 is electrically connected to corresponding conductive layer 502 (word line) across conductive portion 105 in word line pick-up region 103 and core array region 101, according to some implementations. In other words, word line pick-up structures 106 can extend vertically through stack structure 201 at different depths to be electrically connected to the word lines at different levels, respectively, to achieve word line pick-up/fan-out.

As described below in detail, during the gate replacement process, some of second dielectric layers 505 (e.g., silicon nitride) remain intact, thereby forming the dielectric stack structure of stack structure 201 in dielectric portion 107 of word line pick-up region 103, and word line pick-up structure 106 is formed by etching first and second dielectric layers 503 and 505 in dielectric portion 107 of word line pick-up region 103. As a result, word line pick-up structures 106 extend into interleaved first and second dielectric layers 503 and 505 of the dielectric stack structure and are surrounded by first and second dielectric layers 503 and 505 in dielectric portion 107 of word line pick-up region 103. The bottom of each word line pick-up region 103 can be aligned with a corresponding second dielectric layer 505, as opposed to first dielectric layer 503, and the corresponding second dielectric layer 505 can be partially replaced with interconnect line 206 to form the electrical connection between contact structure 202 of word line pick-up region 103 and the corresponding conductive layer 502 (word line). Thus, in some implementations, interconnect line 206 is sandwiched between two first dielectric layers 503, as opposed to two second dielectric layers 505, in the dielectric stack structure in dielectric portion 107 of word line pick-up region 103.

In some implementations as shown in FIG. 5A, due to the relatively large critical dimension compared with the word line contacts in some 3D memory devices caused by its fabrication process, as described below in detail, word line pick-up structure 106 further includes a filler 508 circumscribed by contact structure 202. That is, the word line pick-up opening may not be fully filled with contact spacer 204 and contact structure 202, and the remaining space of the word line pick-up opening may be filled with dielectric materials, including, but not limited to, silicon oxide, silicon nitride, silicon oxynitride, or any combination thereof, as filler 508.

As shown in FIG. 5A, some word line pick-up structures 106 have shoulders 512. Shoulders 512 rest on sidewall shoulders (e.g., sidewall shoulders 711 shown in FIG. 7B) created on a sidewall of an opening (e.g., opening 736 shown in FIG. 7B) during the manufacturing of 3D memory device 100. In some implementations, the sidewall (e.g., sidewall 737 shown in FIG. 7D) is a surface inside the stack structure, which is exposed after the opening (e.g., opening 736 shown in FIG. 7D) is formed, and faces the opening. The sidewall extends generally along the z-direction (with a small angle between the z-direction and its extending direction). Sidewall shoulders are easy to be created as a result of multiple times of etching with masks having a gap or overlay therebetween. They can be a ring-like structure laterally surrounding the sidewall at different depths, or irregular protrusions from sidewalls at different depths. Recognizing the undesired consequences of such sidewall shoulders in the existing technology, such as word line leakage, the present disclosure provides a buffer 510 disposed between second dielectric layers 505 and word line pick-up structure 106 to avoid the undesired consequences. In some implementations, a contact spacer 514 may be further formed in an additional process between buffer 510 and word line pick-up structure 106. Although only two word line pick-up structures 106 are shown in FIG. 5A, and word line pick-up structure 106 with shoulders 512 is described as a primary example of the present implementations, it is understood that there may be other word line pick-up structures 106 in dielectric portion 107 of word line pick-up region 103 not shown in FIG. 5A that also have buffers and contact spacers similar to those described herein.

In some implementations where contact spacer 514 is formed in an additional process, contact spacer 514 and buffer 510 may have the same dielectric material, and thus the boundary therebetween may not be readily discernable. Similarly, when the dielectric material of contact spacer 514 or buffer 510 is the same as that of adjacent first dielectric layers 503, the boundary therebetween may also not be readily discernable. Thus, the boundaries shown in FIG. 5A between any adjacent two or more of first dielectric layers 503, contact spacer 514, and buffer 510 are for illustration purpose only and should not be construed to indicate that the dielectric materials of first dielectric layers 503, contact spacer 514, or buffer 510 cannot be the same. The same applies to the boundaries between any adjacent two or more of first dielectric layers 706, contact spacer 714, and buffer 710 in FIGS. 7D-7H.

The dielectric material can be formed by any of the methods described below in conjunction with FIGS. 7A-7H. For example, the dielectric material can be silicon oxide formed by one or more thin film deposition processes, such as atomic layer deposition (ALD), chemical vapor deposition (CVD), physical vapor deposition (PVD), or any combination thereof. The thickness of the dielectric material in buffer 510, which is measured on a lateral plane defined by the x-direction and the y-direction and perpendicular to the z-direction, may be between 10 nm and 200 nm, according to some implementations. A portion of buffer 510 in the vicinity of the shoulder areas may be etched more significantly during the manufacturing process, thus having a smaller thickness than another portion of buffer 510 further away from the shoulder areas. Even so, the remaining buffer 510 can protect the second dielectric layers from being replaced with conductive layers in the subsequent processes, because the second dielectric layers are not exposed to the openings.

FIG. 5B illustrates an enlarged view of a portion (rectangle CC) of the cross-sectional side view of the 3D memory device 100 shown in FIG. 5A, according to some aspects of the present disclosure. In some implementations, a surface of buffer 510 have a plurality of bumps 515. Bumps 515 may be wavy-like and formed along a direction parallel to a sidewall of the opening (e.g., sidewall 737 in FIG. 7D). When the dielectric material is deposited on the surface of the sidewall by a thin film deposition process, the thin film is formed unevenly on the surface due to the existence of recesses created between second dielectric layers 505 and word line pick-up structures 106. Therefore, bumps 515 are formed in the thin film at locations laterally corresponding to first dielectric layers 503. In some implementations, each of bumps 515 laterally corresponds to one first dielectric layer 503, as shown in FIG. 5B. Here, laterally means in a direction on the x-y plane. In some implementations, contact spacer 514 is formed between buffer 510 and word line pick-up structure 106, and thus may also have a plurality of bumps (not shown) on its surface, which correspond to bumps 515 of buffer 510.

It is noted that the proportional dimensions of bumps (e.g., bumps 515) versus other components (e.g., dielectric layers 503 and 505, or contact structures 202) shown in FIG. 5B do not represent the actual proportional dimensions, and bumps 515 are drawn to be over-sized for illustration purpose only. The actual dimensions of bumps 515 are significantly smaller than those of other components, and thus bumps 515 are not conspicuously shown in FIG. 5A.

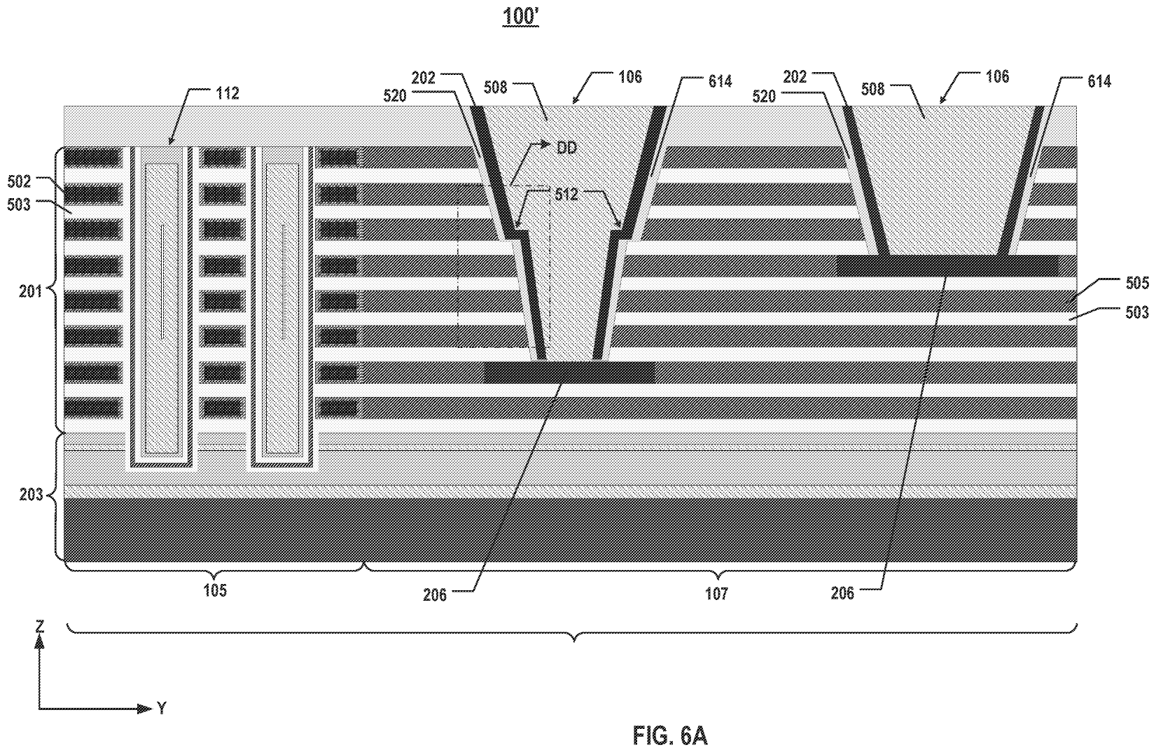

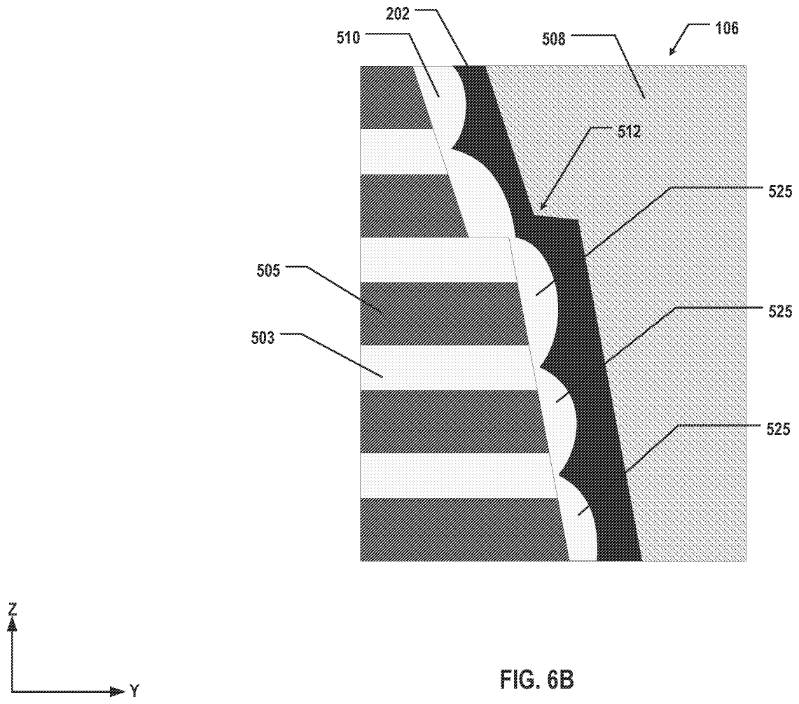

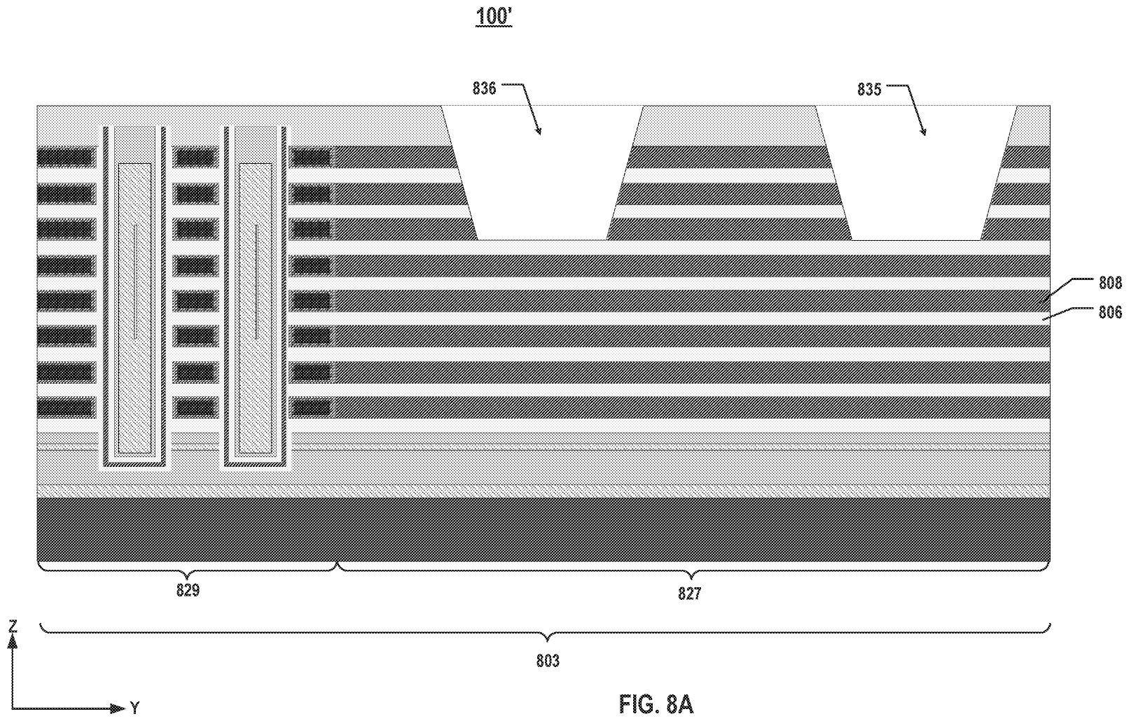

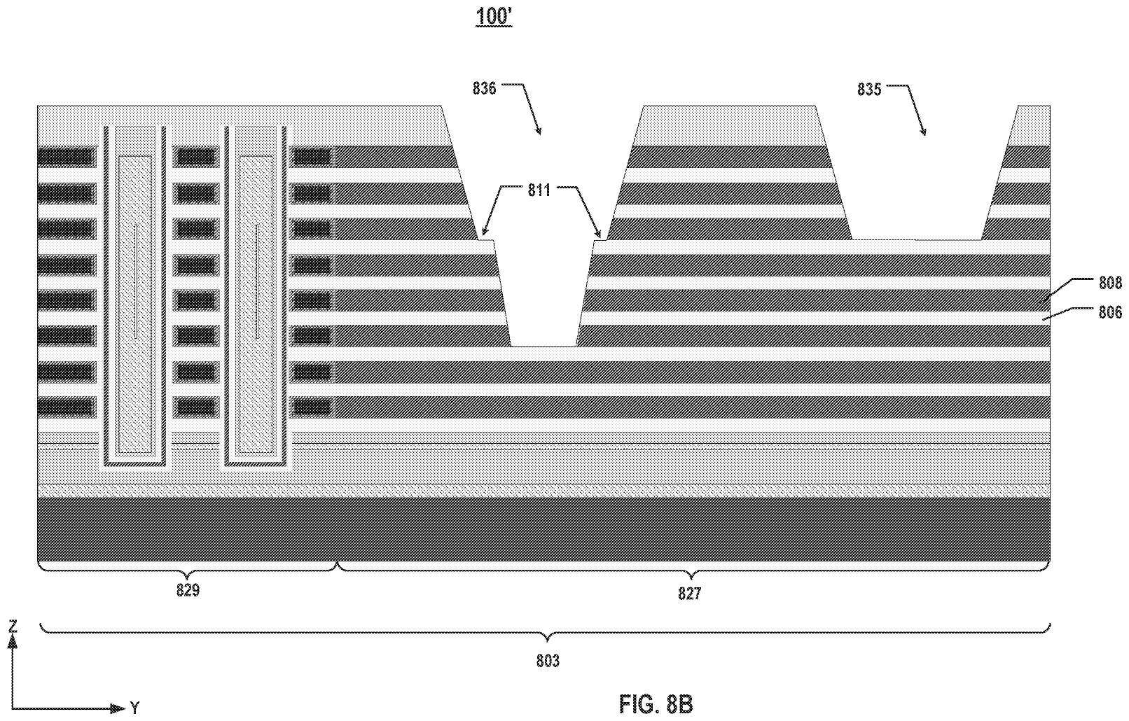

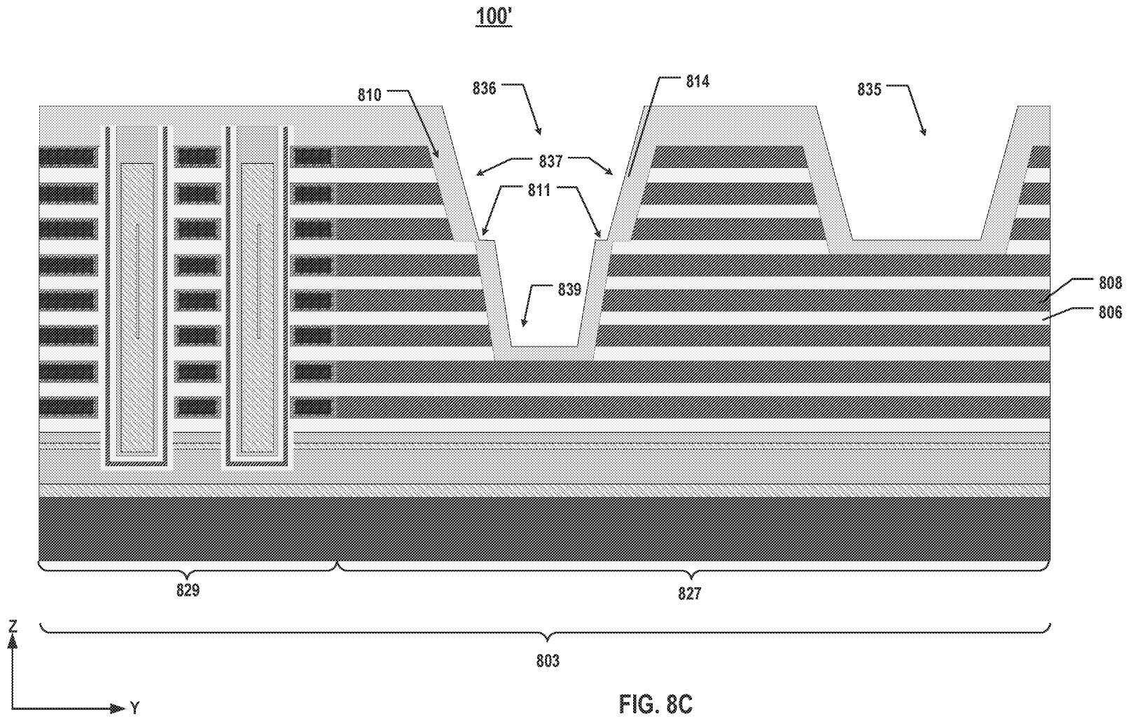

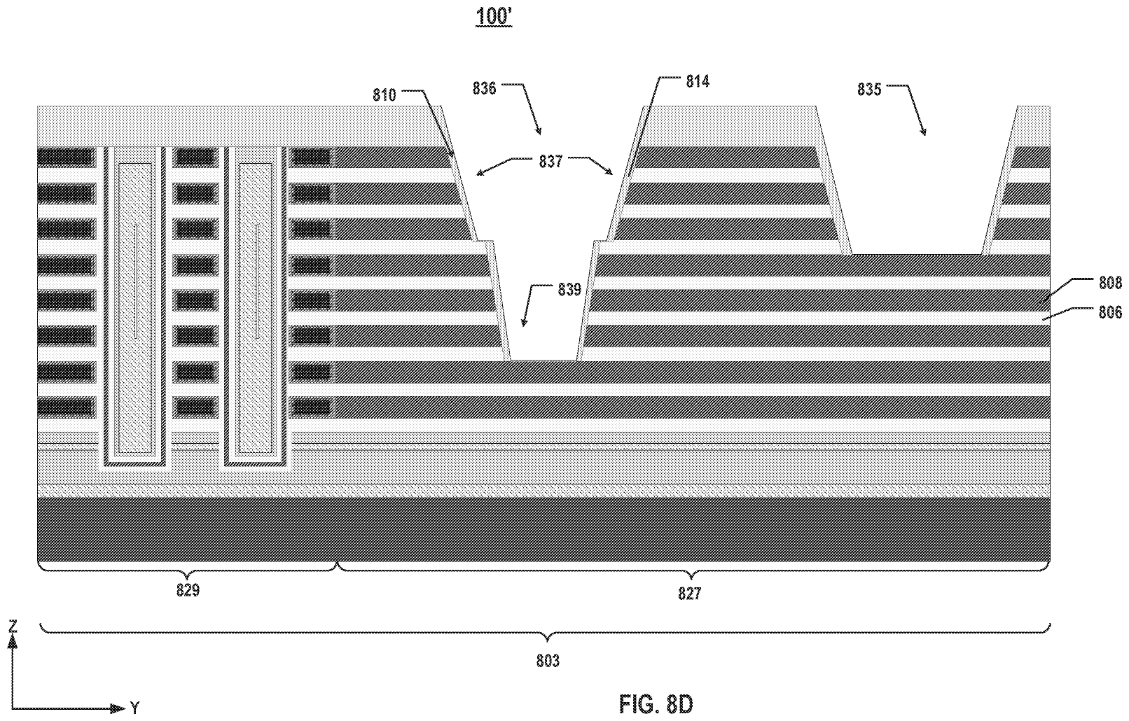

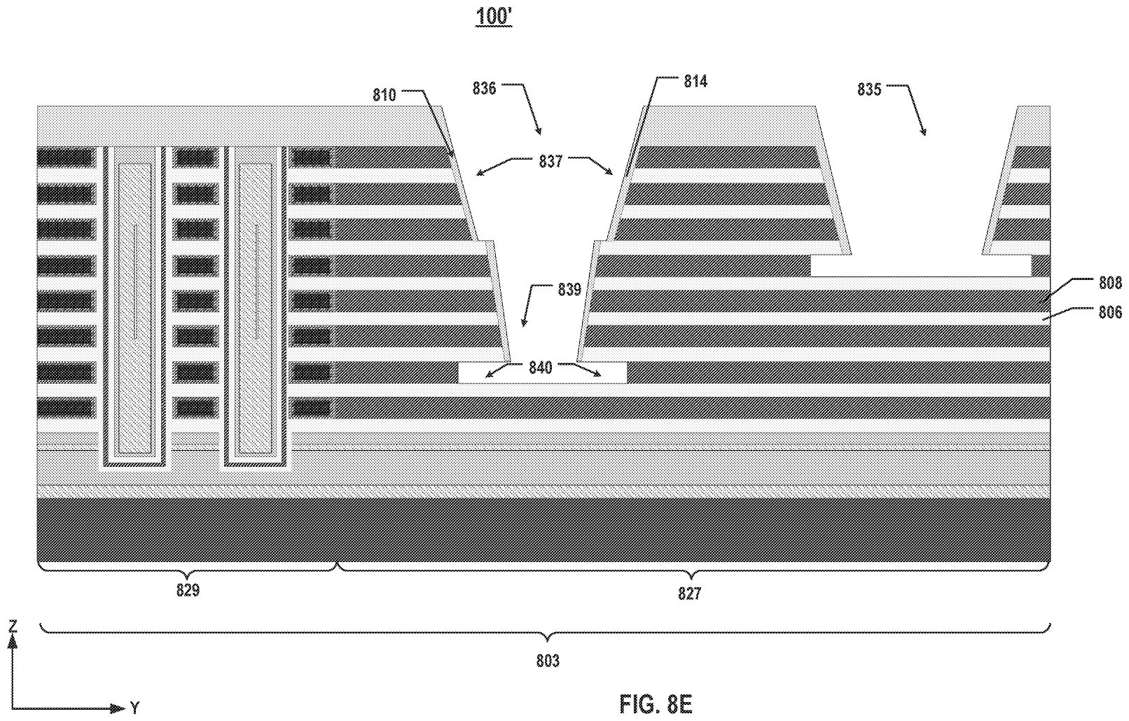

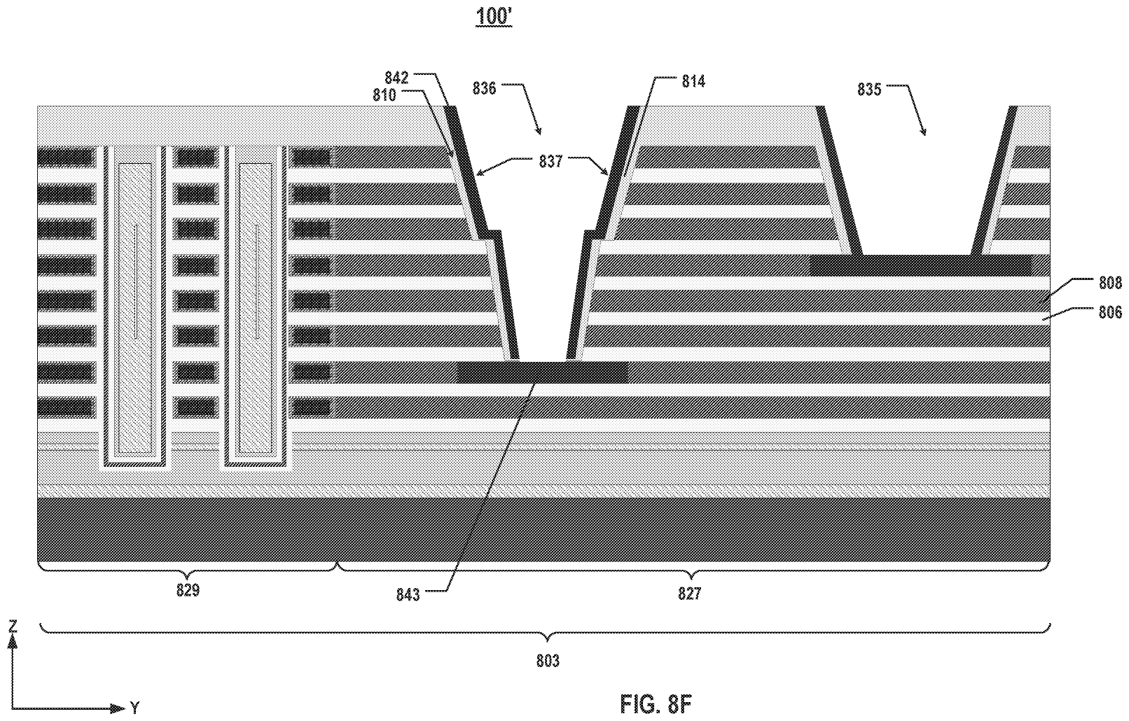

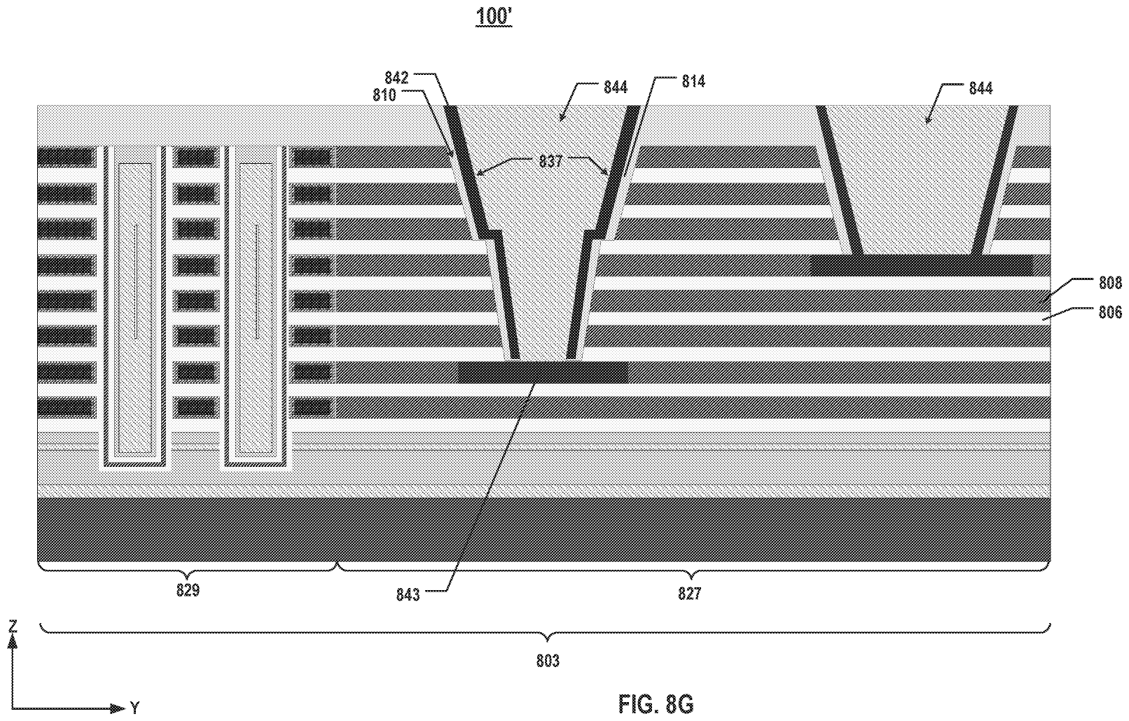

FIG. 6A illustrates a cross-sectional side view of 3D memory device 100′ having word line pick-up structures 106, according to some aspects of the present disclosure. One cross-section may be along the BB direction in core array region 101 in FIG. 1. 3D memory device 100′ generally has the same structure and components as 3D memory device 100. One major difference between them is that a buffer 520 and a contact spacer 614 in 3D memory device 100′ are formed with a different process. Nonetheless, when the process results in the same material for buffer 520 and contact spacer 614, the boundary therebetween may not be readily distinguishable. Similarly, when the dielectric material of contact spacer 614 or buffer 520 is the same as that of adjacent first dielectric layers 503 adjacent, the boundary therebetween may also not be readily discernable. Thus, the boundaries shown in FIG. 6A are for illustration purpose only and should not be construed to indicate that the dielectric materials of first dielectric layers 503, contact spacer 614, or buffer 520 cannot be the same. The same applies to the boundaries between two or more of first dielectric layers 806, contact spacer 814, and buffer 810 in FIGS. 8C-8G.

During the manufacturing process to be described in conjunction with FIGS. 8A-8G, buffer 520 is obtained by oxidizing a portion of second electric layers 505 exposed to the opening. In some implementations, buffer 520 is subsequently covered by contact spacer 614 with the same material. It is understood that the oxidized portion of second electric layers 505 has become another dielectric material (such as silicon oxide, silicon oxynitride, or a mixture of silicon oxide and silicon oxynitride), and thus the lateral length of second electric layers 505 have retreated from the openings; in other words, the lateral length is shorter than the original lateral length before oxidation. Similar to that in 3D memory device 100, the thickness of the dielectric material in buffer 520 may be between 10 nm and 200 nm, according to some implementations.

Another major difference between 3D memory device 100 shown in FIGS. 5A and 3D memory device 100′ shown in FIG. 6A is the location of bumps. FIG. 6B illustrates an enlarged view of a portion (rectangle DD) of the cross-sectional side view of the 3D memory device 100′ shown in FIG. 6A, according to some aspects of the present disclosure. In some implementations, a surface of buffer 520 have a plurality of bumps 525. Bumps 525 may be wavy-like and formed along a direction parallel to a sidewall of the opening (e.g., sidewall 837 in FIG. 8D). When a portion of second dielectric layers 505 is oxidized, the growth of buffer 520 adjacent to the second dielectric layers 505 outpaces that of buffer 520 adjacent to the first dielectric layers 503. As a result, buffer 520 is formed unevenly over the sidewall with bumps 525 formed at locations laterally corresponding to second dielectric layers 505, as opposed to locations laterally corresponding to first dielectric layers 503 in 3D memory device 100. In some implementations, each of bumps 525 laterally corresponds to one second dielectric layer 505, as shown in FIG. 6B. Similarly as above, laterally means in a direction on the x-y plane. In some implementations, contact spacer 614 is formed between buffer 520 and word line pick-up structure 106, and thus may also have a plurality of bumps (not shown) on its surface, which correspond to bumps 525 of buffer 520.

It is noted that the proportional dimensions of bumps (e.g., bumps 525) versus other components (e.g., dielectric layers 503 and 505, or contact structures 202) shown in FIG. 6B do not represent the actual proportional dimensions, and bumps 525 are drawn to be over-sized for illustration purpose only. The actual dimensions of bumps 525 are significantly smaller than those of other components, and thus bumps 525 are not conspicuously shown in FIG. 6A.

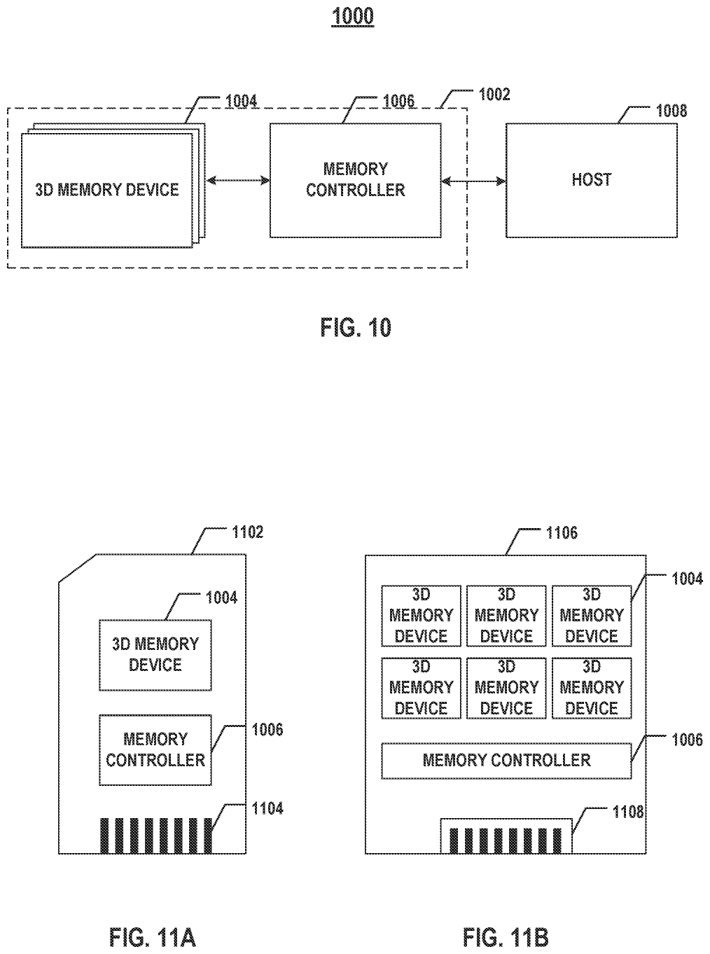

FIG. 10 illustrates a block diagram of an exemplary system 1000 having a 3D memory device, according to some aspects of the present disclosure. System 1000 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 10, system 1000 can include a host 1008 and a memory system 1002 having one or more 3D memory devices 1004 and a memory controller 1006. Host 1008 can be a processor of an electronic device, such as a central processing unit (CPU), or a system-on-chip (SoC), such as an application processor (AP). Host 1008 can be configured to send or receive data to or from 3D memory devices 1004.

3D memory device 1004 can be any 3D memory device disclosed herein, such as 3D memory devices 100 and 100′ depicted in FIGS. 1-6B. In some implementations, each 3D memory device 1004 includes a NAND Flash memory. Consistent with the scope of the present disclosure, word line pick-up structures can replace the staircase structures and word line contacts to achieve word line pick-up/fan-out functions, thereby reducing the manufacturing cost and simplifying the fabrication process.

Memory controller 1006 (a.k.a., a controller circuit) is coupled to 3D memory device 1004 and host 1008 and is configured to control 3D memory device 1004, according to some implementations. For example, memory controller 1006 may be configured to operate the plurality of channel structures via the word lines. Memory controller 1006 can manage the data stored in 3D memory device 1004 and communicate with host 1008. In some implementations, memory controller 1006 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1006 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1006 can be configured to control operations of 3D memory device 1004, such as read, erase, and program operations. Memory controller 1006 can also be configured to manage various functions with respect to the data stored or to be stored in 3D memory device 1004 including, but not limited to bad-block management, garbage collection, logical-to-physical address conversion, wear leveling, etc. In some implementations, memory controller 1006 is further configured to process error correction codes (ECCs) with respect to the data read from or written to 3D memory device 1004. Any other suitable functions may be performed by memory controller 1006 as well, for example, formatting 3D memory device 1004. Memory controller 1006 can communicate with an external device (e.g., host 1008) according to a particular communication protocol. For example, memory controller 1006 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1006 and one or more 3D memory devices 1004 can be integrated into various types of storage devices, for example, be included in the same package, such as a universal Flash storage (UFS) package or an eMMC package. That is, memory system 1002 can be implemented and packaged into different types of end electronic products. In one example as shown in FIG. 11A, memory controller 1006 and a single 3D memory device 1004 may be integrated into a memory card 1102. Memory card 1102 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1102 can further include a memory card connector 1104 electrically coupling memory card 1102 with a host (e.g., host 1008 in FIG. 10). In another example as shown in FIG. 11B, memory controller 1006 and multiple 3D memory devices 1004 may be integrated into an SSD 1106. SSD 1106 can further include an SSD connector 1108 electrically coupling SSD 1106 with a host (e.g., host 1008 in FIG. 10). In some implementations, the storage capacity and/or the operation speed of SSD 1106 is greater than those of memory card 1102.

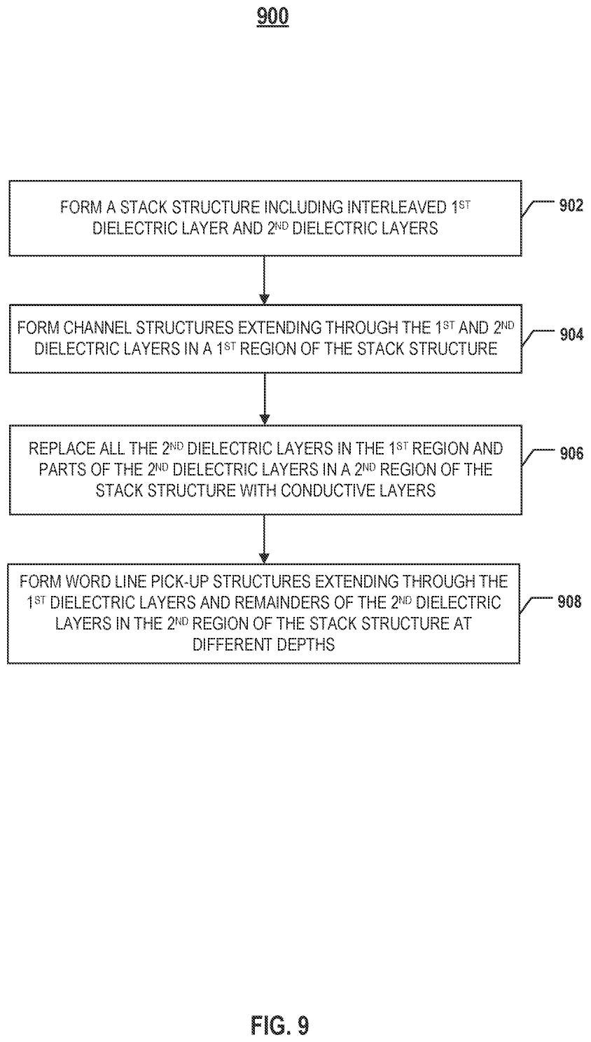

FIGS. 7A-7H illustrate a fabrication process for forming a 3D memory device 100 having word line pick-up structures, according to some aspects of the present disclosure. FIG. 9 illustrates a flowchart of a method 900 for forming an exemplary 3D memory device 100 having word line pick-up structures, according to some implementations of the present disclosure. Examples of the 3D memory device depicted in FIGS. 7A-7H and 9 include 3D memory device 100 depicted in FIGS. 1-5B. FIGS. 7A-7H and 9 will be described together. It is understood that the operations shown in method 900 are not exhaustive and that other operations can be performed as well before, after, or between any of the illustrated operations. Further, some of the operations may be performed simultaneously, or in a different order than that shown in FIG. 9.

Referring to FIG. 9, method 900 starts at operation 902, in which a stack structure including interleaved first dielectric layers (e.g., first material layers 302 in FIG. 3) and second dielectric layers (e.g., second material layers 304 in FIG. 3) is formed. The first dielectric layers can include silicon oxide, and the second dielectric layers can include silicon nitride. In some implementations, to form the stack structure, the first dielectric layers and the second dielectric layers are alternatingly deposited above a substrate (e.g., substrate 203 in FIG. 2). The substrate can be a silicon substrate. The stack structure can be formed by one or more thin film deposition processes including, but not limited to, ALD, CVD, PVD, or any combination thereof.

Method 900 proceeds to operation 904, as illustrated in FIG. 9, in which channel structures (e.g., channel structures 110 in FIG. 1) extending through the first dielectric layers and the second dielectric layers are formed in a first region of the stack structure (e.g., core array region 101 in FIGS. 1 and 3). In some implementations, to form the channel structure, a channel hole extending vertically through the stack structure is formed, and a memory layer and a channel layer are sequentially formed over sidewalls of the channel hole. In some implementations, to form the channel structure, a channel hole extending vertically through the stack structure is formed, and a high-k gate dielectric layer, a memory layer, and a channel layer are sequentially formed over sidewalls of the channel hole. In some implementations, dummy channel structures (e.g., dummy channel structures 112 in FIG. 1) extending through the first dielectric layers and the second dielectric layers are formed in the second region of the stack structure in the same process of forming the channel structures. That is, channel structures and dummy channel structures can be simultaneously formed through the first dielectric layers and the second dielectric layers in the first region and the second region of the stack structure, respectively.

In some implementations, to form channel structures, a plurality of channel holes are opened, such that each channel hole becomes the location for growing an individual channel structure in the later process. In some implementations, fabrication processes for forming channel holes of channel structures include wet etching and/or dry etching, such as deep-ion reactive etching (DRIE). Subsequently, a memory layer (including a blocking layer, a storage layer, and a tunneling layer) and a channel layer are sequentially formed in this order along sidewalls and the bottom surface of the channel hole. In some implementations, the memory layer is first deposited along the sidewalls and bottom surface of the channel hole, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of the channel structure.

In some implementations, a high-k gate dielectric layer is formed before the formation of the memory layer. That is, the high-k gate dielectric layer, memory layer (including the blocking layer, storage layer, and tunneling layer), and the channel layer can be sequentially formed in this order along sidewalls and the bottom surface of the channel hole. In some implementations, the high-k gate dielectric layer is first deposited along the sidewalls and bottom surfaces of the channel hole, the memory layer is then deposited over the high-k gate dielectric layer, and the semiconductor channel is then deposited over the memory layer. The high-k gate dielectric layer can be formed by depositing high-k dielectric materials, such as aluminum oxide, using one or more thin film deposition processes, such as ALD, CVD, PVD, any other suitable processes, or any combination thereof. The blocking layer, storage layer, and tunneling layer can be subsequently deposited in this order using one or more thin film deposition processes, such as ALD, CVD, PVD, any other suitable processes, or any combination thereof, over the high-k gate dielectric layer to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, an aluminum oxide layer, a first silicon oxide layer, a silicon nitride layer, a second silicon oxide layer, and a polysilicon layer (a “SONO” structure) are subsequently deposited to form the high-k gate dielectric layer, the memory layer, and the channel layer of the channel structure.

In some implementations, dummy channel structures (e.g., dummy structures 112 in FIG. 1) can be formed in a word line pick-up region (e.g., word line pick-up region 103 in FIGS. 1-3) of the stack structure (e.g., stack structure 201 in FIGS. 2-3), in the same process of forming the channel structures. To form each dummy channel structure, a dummy channel hole, which is another opening extending vertically through the stack structure, can be formed in the word line pick-up region simultaneously as the channel hole by the same wet etching and/or dry etching, such as DRIE. The dummy channel structure can then be formed simultaneously as the channel structure by the same thin film deposition processes, such as ALD, CVD, PVD, any other suitable processes, or any combination thereof that deposit a memory layer (including a blocking layer, a storage layer, and a tunneling layer) and a channel layer, or a high-k gate dielectric layer, a memory layer (including a blocking layer, a storage layer, and a tunneling layer), and a channel layer. It is understood that in some examples, the dummy channel structures may be formed in a separate process from the channel structures.

Method 900 proceeds to operation 906, as illustrated in FIG. 9, in which all the second dielectric layers in the first region and parts of the second dielectric layers in a second region of the stack structure are replaced with conductive layers, for example, by a gate replacement process. The conductive layer can include a metal.

At the beginning of the gate replacement process, a slit extending through the first dielectric layers and the second dielectric layers and across the first region and the second region of the stack structure is formed. In some implementations, the slit extends vertically through the local contact layer as well. The slit can also extend laterally across the core array region and the word line pick-up region in the x-direction (the word line direction). In some implementations, fabrication processes for forming the slit include wet etching and/or dry etching, such as DRIE, of the first dielectric layers and the second dielectric layers. The etching process through the stack structure may not stop at the top surface of the silicon substrate and may continue to etch part of the silicon substrate to ensure that the slit extends vertically all the way through all the first dielectric layers and second dielectric layers of the stack structure.

Thereafter, the part of the slit in the core array region is covered by a sacrificial layer. In some implementations, the sacrificial layer that is different from the first dielectric layers and the second dielectric layers, such as a polysilicon layer or a carbon layer, is deposited into the slit using one or more thin film deposition processes, such as CVD, PVD, ALD, or any combination thereof, to at least partially fill the slit (covering the exposed first dielectric layers and second dielectric layers in the slit). The sacrificial layer can then be patterned using lithography and wet etching and/or dry etching to remove the part of the sacrificial layer in the word line pick-up region, leaving only the part of the sacrificial layer in the core array region to cover only the part of the slit in the core array region.

Subsequently, the parts of the second dielectric layers in the second region of the stack structure are removed through the slit in the second region of the stack structure. Specifically, the parts of the second dielectric layers in the second region (namely, word line pick-up region) of the stack structure are removed through the slit in the second region of the stack structure. The removal can be performed by wet etching to form lateral recesses, leaving the remainders of second dielectric layers in a dielectric portion of the word line pick-up region intact. In some implementations, the parts of the second dielectric layers are wet etched by applying a wet etchant through the part of the slit in the word line pick-up region that is uncovered by the sacrificial layer, creating lateral recesses interleaved between the first dielectric layers. The wet etchant can include phosphoric acid for etching the second dielectric layers including silicon nitride. In some implementations, one or both of the etching rate and etching time are controlled to remove only the parts of the second dielectric layers in the conductive portion (e.g., conductive portion 105 in FIGS. 1 and 5), leaving the remainders of the second dielectric layers intact in the dielectric portion (e.g., dielectric portion 107 in FIGS. 1 and 5). By controlling the etching time, the wet etchant does not travel all the way to completely remove the second dielectric layers in the word line pick-up region, thereby defining two portions in the word line pick-up region—the dielectric portion in which the second dielectric layers are removed, and the dielectric portion in which the second dielectric layers remain. Since the part of the slit in the core array region is covered by the sacrificial layer that is resistant to the etchant for removing the second dielectric layers, all the second dielectric layers remain intact in the core array region.

Then the slit in the first region of the stack structure is opened. Specifically, the part of the slit in the core array region is re-opened by removing the sacrificial layer to expose the first dielectric layers and the second dielectric layers. In some implementations, the sacrificial layer is selectively etched away from the part of the slit in the core array region, for example, using potassium hydroxide (KOH) for etching the sacrificial layer having polysilicon, to open the part of the slit in the core array region.

After that, the slit in the second region of the stack structure is covered. Specifically, the lateral recesses and the part of the slit in the word line pick-up region are covered by another sacrificial layer. In some implementations, the sacrificial layer that is different from the first dielectric layers and the second dielectric layers, such as a polysilicon layer or a carbon layer, is deposited into the lateral recesses and the slit using one or more thin film deposition processes, such as ALD, CVD, PVD, or any combination thereof, to at least partially fill the slit (covering the exposed first dielectric layers and second dielectric layers). The sacrificial layer can then be patterned using lithography and wet etching and/or dry etching to remove the part of the sacrificial layer in the core array region, leaving only the part of the sacrificial layer in the word line pick-up region to cover only the lateral recesses and the part of the slit in the word line pick-up region, but not in the core array region. It is understood that the lateral recesses may be considered as parts of the slit in the word line pick-up region. Thus, even if only the lateral recesses are fully or partially filled by the sacrificial layer, the part of the slit in the word line pick-up region may still be considered as being covered.

Later, all the second dielectric layers in the first region of the stack structure are removed through the slit in the first region of the stack structure. Specifically, all the second dielectric layers in the core array region are fully removed by wet etching to form lateral recesses. In some implementations, the second dielectric layers are wet etched by applying a wet etchant through the part of the slit in the core array region that is uncovered by the sacrificial layer, creating the lateral recesses interleaved between the first dielectric layers. The wet etchant can include phosphoric acid for etching the second dielectric layers including silicon nitride. In some implementations, one or both of the etching rate and etching time are controlled to ensure that all the second dielectric layers in the core array region are completely etched away. Since the part of the slit in the word line pick-up region is covered by the sacrificial layer that is resistant to the etchant for removing the second dielectric layers, the remainders of the second dielectric layers in the dielectric portion of the word line pick-up region remain intact.

Afterward, the slit in the second region of the stack structure is opened. Specifically, the part of the slit in the word line pick-up region is re-opened by removing the sacrificial layer to expose the first dielectric layers and the remainders of the second dielectric layers in the word line pick-up region. In some implementations, the sacrificial layer is selectively etched away from the part of the slit in the word line pick-up region, for example, using KOH for etching the sacrificial layer having polysilicon, to open the part of the slit (and the lateral recesses) in the word line pick-up region.

Finally, the conductive layers are deposited through the slit in the first region and the second region of the stack structure. Specifically, the conductive layers are deposited into lateral recesses in the core array region and the conductive portion of the word line pick-up region through the slit. In some implementations in which high-k gate dielectric layers are not formed in the channel structures, the high-k gate dielectric layers are deposited into the lateral recesses prior to the conductive layers, such that the conductive layers are deposited on and surrounded by the high-k gate dielectric layers. In some implementations in which high-k gate dielectric layers are formed in the channel structures, the high-k gate dielectric layers are not deposited into the lateral recesses prior to the conductive layers, such that the conductive layers are deposited on and surrounded by the first dielectric layers. The conductive layers, such as metal layers, can be deposited using one or more thin film deposition processes, such as ALD, CVD, PVD, any other suitable processes, or any combination thereof.

As described above, the removal of the second dielectric layers (stack sacrificial layers, e.g., having silicon nitride) can be performed separately in the core array region and the word line pick-up region by partially covering the slit in the core array region or the word line pick-up region to allow the second dielectric layers to be removed at different scopes (e.g., fully removal in the core array region and partial removal in the word line pick-up region). It is understood that in another gate replace process, the removal of the second dielectric layers may be performed first in the core array region, and then in the word line pick-up region.

After the gate replacement processes described above, the stack structure can be redefined into two stack structures—a conductive stack structure including interleaved conductive layers and first dielectric layers in the core array region as well as in the conductive portion of the word line pick-up region, and a dielectric stack structure including interleaved first dielectric layers and the remainders of second dielectric layers in the dielectric portion of the word line pick-up region. That is, all the second dielectric layers in the core array region and parts of the second dielectric layers in the word line pick-up region of the stack structure are replaced with the conductive layers, according to some implementations. Moreover, in some examples, since the dielectric stack structure in the dielectric portion of the word line pick-up region remains intact during the gate replacement process (without removal of the remainders of the second dielectric layers therein), the dummy channel structures may not need to be formed in the dielectric portion of the word line pick-up region to provide mechanical support when removing the second dielectric layer.

Referring back to FIG. 9, method 900 proceeds to operation 908, as illustrated in FIG. 9, in which word line pick-up structures extending through the first dielectric layers and remainders of the second dielectric layers in the second region of the stack structure are formed at different depths.

In some implementations, to form the word line pick-up structures, word line pick-up openings extending through the first dielectric layers and the remainders of the second dielectric layers in the second region of the stack structure are formed at different depths to expose the remainders of the second dielectric layers in the second regions of the stack structure, respectively. As illustrated in FIG. 7A, a plurality of openings 735 are formed by etching with a first mask. The plurality of openings 735 have the same depths, all extending vertically through a number of pairs of first dielectric layers 706 and second dielectric layers 708 of the dielectric stack structure in a dielectric portion 727 of a word line pick-up region 703. A conductive portion 729 of the word line pick-up region 703 is intact from the etching.

Subsequently, as illustrated in FIG. 7B, a different mask is used to etch some of the openings 735 to obtain openings 736 that extend further vertically into the dielectric stack structure. Thus, openings 736 have a larger depth than openings 735. The method forming openings with different depths is also known as a chopping process. As used herein, a “chopping” process is a process that increases the depth of one or more openings extending through a dielectric stack structure including interleaved first and second dielectric layers by a plurality of etching cycles. Each etch cycle can include one or more dry etch and/or wet etch processes that etch one pair of first and second dielectric layers, i.e., reducing the depth by one dielectric layer pair. The purpose of the chopping process is to make multiple openings at different depths. Accordingly, depending on the number of openings, a certain number of chopping processes, along with a number of chopping masks, may be needed. It is understood that the number of chopping masks, the sequence of the chopping masks, the design (e.g., the number and pattern of openings) of each chopping mask, and/or the reduced depth by each chopping process (e.g., the number of etching cycles) may affect the specific depth of each opening after the chopping process. A detailed description of the chopping process can be referenced in U.S. Patent Application No. 16/881,168, filed on May 22, 2022, and U.S. patent application Ser. No. 16/881,339, filed on May 22, 2022, both of which are incorporated by reference in their entireties herein.

It is understood that the chopping process can be more easily performed through a dielectric stack structure including interleaved first and second dielectric layers (e.g., silicon oxide and silicon nitride), as opposed to a conductive stack structure including interleaved conductive layers and dielectric layers (e.g., metal and silicon oxide) due to the etching properties of the different materials. Thus, the dielectric stack structure remains after the gate replacement process in dielectric portion 727 of word line pick-up region 703 is suitable for forming openings 735, 736 for word line pick-up structures at different depths using the chopping process, according to some implementations. Although only two openings 735, 736 are shown in FIGS. 7B-7H, it is understood that more openings of the same or different depths are also formed by the chopping process. Unless otherwise noted, the following description in conjunction with FIGS. 7B-7H regarding openings 735, 736 is also applicable to all other such openings in 3D memory device 100.

The chopping process is prone to create sidewall shoulders, such as sidewall shoulders 711 shown in FIG. 7B. These sidewall shoulders may pose a threat to the subsequent manufacturing process, because second dielectric layers 708 in the vicinity of the shoulders may be exposed to opening 736 when the bottom of opening 736 is later etched in the gate replacement process. The exposed second dielectric layers 708 are thus replaced with the conductive layers that are only supposed to replace the second dielectric layers 708 right beneath the bottom of opening 736 to form the interconnect line (e.g., interconnect line 206 in FIG. 5A). As a result, the contact structure (e.g., contact structure 202 in FIG. 5A) of the word line pick-up structure is electrically connected to both the interconnect line and the newly formed conductive layers near the shoulders, causing word line leakage during operation of 3D memory device 100.

To mitigate this undesired consequence, the present disclosure provides an additional process of converting a portion of second dielectric layers (e.g., second dielectric layers 708) into another dielectric material (i.e., third dielectric material). The converted portion is the portion of the second dielectric layers closest to the opening (e.g., opening 736). The third dielectric material is different from that of the second dielectric layers (i.e., second dielectric material). The third dielectric material may or may not be the same as that of first dielectric layers (e.g., first dielectric layers 706) (i.e., first dielectric material). In one example, the second dielectric material is silicon nitride, and the first and third dielectric materials are both silicon oxide. FIGS. 7A-7H demonstrate various implementations of the abovementioned conversion.

In some implementations, as shown in FIG. 7C, recesses 713 are created in second dielectric layers 708 exposed after the openings 735, 736 are formed. Recesses 713 are generally lateral as they extend in a direction perpendicular to the z-direction (vertical direction). In some implementations, recesses 713 may be formed by removing parts of second dielectric layers 708 abutting a sidewall (e.g., sidewall 737 in FIG. 7D) of the openings 735, 736 (and thus closest to word line pick-up structures after their formation). The removal can be realized by one or both of wet etching (such as using a wet etchant for the dielectric material constituting second dielectric layers 708 (e.g., silicon nitride)) and dry etching. Upon completion of the removal, a smooth surface of openings 735, 736 (as shown in FIG. 7B) may become a seesaw-like surface with recesses 713 interleaved with non-etched first dielectric layers 706, as shown in FIG. 7C.

In some implementations, the lateral dimensions of recesses 713 can be controlled by one or both of the etching rate and the etching time. The dimension for each recess 713 can be calculated as a lateral distance between the edge of second dielectric layer 708 adjoining the recess 713 and the average edge of the upper and lower first dielectric layers 706 adjacent to that second dielectric layer 708. The dimension of each recess 713 can be between about 10 nm and about 200 nm, such as between 10 nm and 200 nm. The dimension of one particular recess 713 can be 10 nm, 20 nm, 30 nm, 40 nm, 50 nm, 60 nm, 70 nm, 80 nm, 90 nm, 100 nm, 120 nm, 140 nm, 160 nm, 180 nm, and 200 nm, or any range bounded by the lower end of any of these values, or in any range defined by any two of these values.

Afterwards, as shown in FIG. 7D, a dielectric material can be deposited inside openings 735, 736 using one or more thin film deposition processes, such as ALD, CVD, PVD, or any combination thereof. In some implementations, the dielectric material is silicon oxide and the deposition process is an ALD process. After the deposition process is carried out for a certain period of time, the dielectric material can fill in recesses 713. The filled-in recesses 713 thus become buffers 710 sandwiched between second dielectric layers 708 and openings 735, 736. The outer edges of buffers 710 may be flush with the outer edges of their respective adjacent first dielectric layers 706, thus smoothening sidewalls 737 of openings 735, 736. Sidewall shoulders 711 may be at least partially covered by buffers 710 as well. A thickness of each buffer 710 is equivalent to the dimension of each recess 713 corresponding to that buffer 710. Thus, the thickness of buffers 710 can be between about 10 nm and about 200 nm, such as between 10 nm and 200 nm. The thickness of one particular buffer 710 can be 10 nm, 20 nm, 30 nm, 40 nm, 50 nm, 60 nm, 70 nm, 80 nm, 90 nm, 100 nm, 120 nm, 140 nm, 160 nm, 180 nm, and 200 nm, or any range bounded by the lower end of any of these values, or in any range defined by any two of these values. The same deposition process that forms buffers 710 may also form a layer of dielectric material above the bottoms of openings 735, 736, which is subsequently etched to form interconnect lines, as will be discussed in detail hereinafter.

In some implementations, after the formation of buffers 710, the deposition process can be extended to form contact spacers 714 that cover sidewalls 737 and bottoms 739 of openings 735, 736. During the process, the dielectric material can also be formed on the surface of sidewall shoulders 711 so that sidewall shoulders 711 are further covered by the dielectric material. In other implementations, contact spacers 714 may be formed by a process different from the deposition process that forms buffers 710. For example, contact spacers 714 may be formed by a second deposition process using CVD or PVD process. The material deposited in the second deposition process forming contact spacers 714 (i.e., the fourth dielectric material) may or may not be the same as the dielectric material deposited in recesses 713 in the first deposition process that forms buffers 710 (i.e., the third dielectric material). As discussed above in conjunction with FIG. 5A, where contact spacers 714 and buffers 710 have the same dielectric material, their boundaries may not be readily discernable. The thickness of contact spacers 714 can be between about 5 nm and about 40 nm, such as between 5 nm and 40 nm. The thickness of one particular contact spacer 714 can be 5 nm, 6 nm, 7 nm, 8 nm, 9 nm, 10 nm, 12 nm, 14 nm, 15 nm, 16 nm, 18 nm, 20 nm, 22 nm, 24 nm, 25 nm, 26 nm, 28 nm, 30 nm, 32 nm, 34 nm, 35 nm, 36 nm, 38 nm, and 40 nm, or any range bounded by the lower end of any of these values, or in any range defined by any two of these values. Thus, both bottoms 739 and sidewall shoulders 711 of openings 735, 736 are covered by contact spacers 714 having about the same thickness of the dielectric material.

In some implementations, to form the word line pick-up structures, the part of deposited layers on the bottoms of word line pick-up openings is removed to expose the respective part of the remainder of second dielectric layers. As illustrated in FIG. 7E, when contact spacers 714 are formed above bottoms 739 of openings 735, 736, they are removed along with the layers formed previously in the first deposition process that forms buffers 710 by, for example, dry etching, to expose part of second dielectric layers 708 in dielectric portion 727 of word line pick-up region 703. In some implementations, one or more of the etching rate, direction, and duration are controlled to etch only the part of the deposited layers on bottoms 739, but not on sidewalls 737, of openings 735, 736, i.e., “punching” through the deposited layers in the z-direction to expose only corresponding second dielectric layers 708 from the bottom, but not other second dielectric layers 708 from sidewalls 737.

According to the present disclosure, because buffers 710, along with contact spacers 714 in some implementations, are formed between second dielectric layers 708 and openings 736, and sidewall shoulders 711 (especially the upper surface thereof) are covered thereby, etching of the deposited layers on bottoms 739 of openings 735, 736 will not punch through buffers 710 or contact spacers 714 to expose second dielectric layers 708 adjacent to sidewalls 737. Only second dielectric layers 708 beneath bottoms 739 of openings 735, 736 are exposed. Thus, in the subsequent process forming interconnect lines, no second dielectric layers 708 adjacent to sidewalls 737 will be replaced with conductive layers. The result eliminates word line leakage and enhances the performance of the 3D memory devices according to the present disclosure.

In some implementations, to form the word line pick-up structures, parts of the remainders of the second dielectric layers in the second region of the stack structure are replaced with interconnect lines, respectively, through the word line pick-up openings, such that the interconnect lines are in contact with the conductive layers, respectively, in the second region of the stack structure. In some implementations, to replace the parts of the second dielectric layers with the interconnect lines, the exposed part of the remainder of the second dielectric layer is etched through the word line pick-up opening to expose the respective conductive layer in the second region of the stack structure, and the respective interconnect line is deposited through the word line pick-up opening to be in contact with the exposed respective conductive layer in the second region of the stack structure.

As illustrated in FIG. 7F, a part of second dielectric layers 708 exposed from bottoms 739 of openings 735, 736 is removed by wet etching to form lateral slits 740, leaving the remainder of second dielectric layers 708 at the same level, as well as other second dielectric layers 708 at other levels, in dielectric portion 727 of word line pick-up region 703 intact. In some implementations, some lateral slits 740 can expose corresponding conductive layers at the same level in conductive portion 729 of word line pick-up region 703. In some implementations, the part of second dielectric layers 708 is wet etched by applying a wet etchant through openings 735, 736, creating lateral slits 740 sandwiched between first dielectric layers 706. The wet etchant can include phosphoric acid for etching second dielectric layers 708, which can include silicon nitride. In some implementations, one or both of the etching rate and etching time are controlled to remove only part of second dielectric layers 708 that is enough to expose corresponding conductive layers 732 at the same level in conductive portion 729. By controlling the etching time, the wet etchant does not travel all the way to completely remove second dielectric layers 708 in dielectric portion 727. As a result, dummy channel structures 716 may not need to be formed in dielectric portion 727 of word line pick-up region 703 to provide mechanical support when removing second dielectric layers 708. As illustrated in FIG. 7F, since sidewalls 737 of openings 735, 736 are still covered by contact spacers 714 (e.g., silicon oxide) and second dielectric layers 708 are further protected by buffers 710 (e.g., silicon oxide), both of which are resistant to the etchant for removing second dielectric layers 708 (e.g., silicon nitride), second dielectric layers 708 at other levels remain intact in dielectric portion 727.

As illustrated in FIG. 7G, interconnect lines 743 are formed by depositing conductive layers through openings 735, 736 to fill lateral slits 740. The conductive layers, such as metal layers, can be deposited using one or more thin film deposition processes, such as ALD, CVD, PVD, any other suitable processes, or any combination thereof. One or both of the deposition rate and duration may be controlled to ensure that interconnect lines 743 can be in contact with the exposed corresponding conductive layers 732 at the same level as lateral slits 740. In other words, second dielectric layers 708 exposed from bottoms 739 of the corresponding openings 735, 736 can be partially replaced with corresponding interconnect lines 743 in dielectric portion 727 of word line pick-up region 703, while other second dielectric layers 708 at other levels in dielectric portion 727 remain intact.

In some implementations, to form the word line pick-up structures, contact structures are formed in the word line pick-up openings in contact with the interconnect lines, respectively. As illustrated in FIG. 7G, contact structures 742 are formed on sidewalls 737 of openings 735, 736 and are in contact with interconnect lines 743. Contact structures 742 can be formed in the same process of forming interconnect lines 743 by depositing the conductive layer not only into lateral slits 740, but also on sidewalls 737 and bottoms 739 of openings 735, 736, using one or more thin film deposition processes, such as ALD, CVD, PVD, any other suitable processes, or any combination thereof.

In some implementations, to form the word line pick-up structures, a filler is formed in the word line pick-up opening after forming the respective contact structure. As illustrated in FIG. 7H, fillers 744 are formed in openings 735, 736 (shown in FIG. 7G) to fully or partially fill openings 735, 736. Fillers 744, such as dielectric layers, can be deposited using one or more thin film deposition processes, such as ALD, CVD, PVD, any other suitable processes, or any combination thereof. The excess portions of the conductive layers and dielectric layers for forming contact structures 742 and fillers 744 can be removed by using chemical mechanical polishing (CMP).

FIGS. 8A-8G illustrate a fabrication process for forming a 3D memory device 100′ having word line pick-up structures, according to some aspects of the present disclosure. Method 900 illustrated in FIG. 9 is also applicable to forming 3D memory device 100′ having word line pick-up structures. Examples of the 3D memory device depicted in FIGS. 8A-8G and 9 include 3D memory device 100′ depicted in FIGS. 1-4 and 6A-6B.

Operations 902, 904, and 906 forming 3D memory device 100′ are the same as those forming 3D memory device 100 described above, the details of which are not repeated herein for brevity purposes.

After the formation of a stack structure including interleaved first dielectric layers and second dielectric layers, the formation of channel structures extending through the first and second dielectric layers in a first region of the stack structure, and replacement of all the second dielectric layers in the first region and parts of the second dielectric layers in a second region of the stack structure with conductive layers, method 900 proceeds to operation 908, as illustrated in FIG. 9, in which word line pick-up structures extending through the first dielectric layers and remainders of the second dielectric layers in the second region of the stack structure are formed at different depths.

Referring to FIGS. 8A and 8B, the formation of word line pick-up openings 835, 836 extending into the stack structure at different depths, which includes undesired sidewall shoulders 811, is the same as that depicted in FIGS. 7A and 7B, and thus is not repeated herein for brevity purposes. A conductive portion 829 of the word line pick-up region 803 is intact from the etching. Sidewall shoulders 811 may pose a threat to the subsequent manufacturing process, because second dielectric layers 808 in the vicinity of the shoulders may be exposed to opening 836 when the bottom of opening 836 is later etched in the gate replacement process. The exposed second dielectric layers 808 are thus replaced with the conductive layers that are only supposed to replace the second dielectric layers 808 right beneath the bottom of the opening to form the interconnect line (e.g., interconnect line 206 in FIG. 6A). As a result, the contact structure (e.g., contact structure 202 in FIG. 6A) of the word line pick-up structures is electrically connected to both the interconnect line and the newly formed conductive layers near the shoulders, causing word line leakage during operation of 3D memory device 100′.

To mitigate this undesired consequence, the present disclosure provides an additional process of converting a portion of second dielectric layers (e.g., second dielectric layers 808) into another dielectric material (i.e., third dielectric material). The converted portion is the portion of the second dielectric layers closest to the opening (e.g., opening 836). The third dielectric material is different from that of the second dielectric layers (i.e., second dielectric material). The third dielectric material may or may not be the same as that of first dielectric layers (e.g., first dielectric layers 806) (i.e., first dielectric material). In one example, the second dielectric material is silicon nitride, the first dielectric material is silicon oxide, and the third material is silicon oxide, silicon oxynitride, or a mixture of silicon oxide and silicon oxynitride. FIGS. 8A-8G demonstrate various implementations of the abovementioned conversion.

In some implementations, as shown in FIG. 8C, an oxidation process is used to change the composition of a portion of second dielectric layers 808 in a dielectric portion 827 of a word line pick-up region 803. The oxidation process can be of any suitable manners, such as thermal oxidation or wet chemical oxidation (e.g., using chemicals containing ozone), which is carried out on sidewalls 837 of openings 835, 836. Compared with oxide layers formed by thin film deposition, oxide layers formed by oxidation are native oxide layers and have a higher quality (e.g., higher density and/or higher dielectric strengths) and a cleaner interface (e.g., less dangling bonds at the interface). The thickness of the oxide layers can be controlled by one or both of the oxidation temperature and time depending on the type of oxidation process applied. Either dry oxidation using molecular oxygen as the oxidant or wet oxidation using water vapor as the oxidant can be used to form native oxide layers at a temperature, for example, not greater than about 850° C.

The oxidized portion of second dielectric layers 808 is the end of second dielectric layers 808 closest to word line pick-up openings 835, 836 (and thus closest to word line pick-up structures after their formation). The oxidized portion of second dielectric layers 808 may serve as buffers 810, similar to buffers 710 in 3D memory device 100 depicted in FIGS. 5A and 7D-7H. As a result, the lateral length of second dielectric layers 808 has retreated from openings 835, 836; in other words, the lateral length after oxidation is shorter than the original lateral length before oxidation. In some implementations, the portion of second dielectric layers 808 closest to openings 835, 836 is oxidized by a wet chemical oxidation process. Wet chemicals including ozone can be used to oxidize the portion of second dielectric layers 808 closest to word line pick-up openings 835, 836 to form buffers 810. In some implementations, the wet chemical is a mixture of hydrofluoric acid and ozone (e.g., FOM). For example, hydrofluoric acid has a concentration of 49% in the ultra-pure water. The thickness of the resulting native oxide layer can be controlled by one or more of the wet chemical compositions, temperature, and time. It is understood that the native oxide layers can be formed using any other suitable processes, such as in situ steam generation (ISSG) process, which uses oxygen gas and hydrogen gas to create water in the form of steam.

In some implementations, the thermal oxidation is performed between about 500° C. and about 850° C., such as between 500° C. and 850° C. (e.g., 500° ° C., 550° C., 600° ° C., 650° C., 700° C., 750° C., 800° ° C., and 850° C., any range bounded by the lower end by any of these values, or in any range defined by any two of these values). In some implementations, the thermal oxidation is performed at about 700° C., such as 700° C. As thermal oxide incorporates silicon consumed from the dielectric stack and oxygen supplied from the ambient, native oxide layers can grow in multiple directions. Thus, in addition to the formation of buffers 810, native oxide layers can also grow above sidewalls 837 and bottoms 839 of openings 835, 836 to become contact spacers 814. Similar to buffers 710 of 3D memory device 100, the thickness of buffers 810 of 3D memory device 100′ can be between about 10 nm and about 200 nm, such as between 10 nm and 200 nm, and the thickness of one particular buffer 810 can be 10 nm, 20 nm, 30 nm, 40 nm, 50 nm, 60 nm, 70 nm, 80 nm, 90 nm, 100 nm, 120 nm, 140 nm, 160 nm, 180 nm, and 200 nm, or any range bounded by the lower end of any of these values, or in any range defined by any two of these values. Similar to contact spacers 714 of 3D memory device 100, the thickness of contact spacers 814 of 3D memory device 100′ can be between about 5 nm and about 40 nm, such as between 5 nm and 40 nm, and the thickness of one particular contact spacer 814 can be 5 nm, 6 nm, 7 nm, 8 nm, 9 nm, 10 nm, 12 nm, 14 nm, 15 nm, 16 nm, 18 nm, 20 nm, 22 nm, 24 nm, 25 nm, 26 nm, 28 nm, 30 nm, 32 nm, 34 nm, 35 nm, 36 nm, 38 nm, and 40 nm, or any range bounded by the lower end of any of these values, or in any range defined by any two of these values. In some implementations, the thickness of dielectric layers (which include buffers 810 and, in some implementations, contact spacers 814) near bottoms 839 of openings 835, 836 is smaller than that of the dielectric layers near the tops of openings 835, 836, which is caused due to oxidation in a hole with a large depth-to-diameter ratio.

In some implementations, contact spacers 814 include not only the native oxide layers grown above sidewalls 837, but also silicon oxide from first dielectric layers 806, because the composition of the native oxide layers and that of first dielectric layers 806 are the same or very similar (e.g., both including silicon oxide). When the native oxide layers and first dielectric layers 806 include the same oxide materials, it becomes difficult to discern the boundary between these two types of layers, which is not delineated in FIGS. 6A and 8C-8G. That said, it is understood that depending on the oxidization processes (e.g., the extent to which nitrogen atoms and ions are removed from the native oxide), the native oxide can be entirely silicon oxide, entirely silicon oxynitride, and a mixture of silicon oxide and silicon oxynitride. As a result, in other implementations, each of buffers 810 and contact spacers 814 includes one or both of silicon oxide and silicon oxynitride. Both silicon oxide and silicon oxynitride are dielectric materials.

In some implementations, to form the word line pick-up structures, the part of oxidized layers on the bottoms of word line pick-up openings is removed to expose the respective part of the remainder of second dielectric layers. As illustrated in FIG. 8D, when contact spacers 814 are formed above bottoms 839 of openings 835, 836, they are removed along with the layers formed previously in the oxidation process that forms buffers 810 by, for example, dry etching, to expose part of second dielectric layers 808 in dielectric portion 827 of word line pick-up region 803. This “punching” process is similar to that described in conjunction with FIG. 7E above, and thus is not repeated herein for brevity purposes.

In some implementations, the part of dielectric layers on bottoms 839 of openings 835, 836 is removed along with the part of dielectric layers on sidewalls 837 thereof by isotropic etching, such as wet etching. Because the dielectric layers along sidewalls 837 (which include buffers 810 and, in some implementations, contact spacers 814) are substantially thicker than that on bottoms 839 of openings 835, 836 (which only include contact spacers 814), when the part of the dielectric layers on bottoms 839 has been etched through, the part of the dielectric layers on sidewalls 837 can be partially etched, leaving the dielectric layers covering only sidewalls 837. In other words, the thickened dielectric layers along sidewalls 837 are etched-back, leaving thinner dielectric layers on sidewalls 837, according to some embodiments. The etching rate or etching time of any suitable isotropic etching process can be controlled to fully etch through dielectric layers on bottoms 839 of openings 835, 836, but partially etch back dielectric layers on sidewalls 837 of openings 835, 836.

The formation of interconnect lines 843, contact structures 842, and fillers 844 of word line pick-up structures of 3D memory device 100′ according to FIGS. 8E-8G are respectively similar to the formation of interconnect lines 743, contact structures 742, and fillers 744 of word line pick-up structures of 3D memory device 100 according to FIGS. 7F-7H, and thus is not repeated herein for brevity purposes. For example, interconnect lines 843 are formed by depositing conductive layers through openings 835, 836 to fill lateral slits 840.

For each word line pick-up structure of the 3D memory devices according to the present disclosure that has a shoulder inside the word line pick-up opening, a buffer is formed between at least some of the dielectric layers and a sidewall of the opening. The thickness of the buffer can be controlled to be large enough to protect the dielectric layers abutting the sidewall from being exposed in the opening due to subsequent etching and being replaced by conductive layers. Compared with the existing technology, the 3D memory devices according to the present disclosure reduce or prevent leakage current in the word line pick-up structures, thereby enhancing performance of the 3D memory devices.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A method for forming a three-dimensional (3D) memory device, comprising:
forming a stack structure comprising interleaved first dielectric layers and second dielectric layers, the first dielectric layers comprising a first dielectric material and the second dielectric layers comprising a second dielectric material different from the first dielectric material;
forming channel structures extending through the first dielectric layers and the second dielectric layers in a first region of the stack structure;
replacing all the second dielectric layers in the first region and parts of the second dielectric layers in a second region of the stack structure with conductive layers; and
forming word line pick-up structures extending through the first dielectric layers and remainders of the second dielectric layers in the second region of the stack structure at different depths, each word line pick-up structure extending along a sidewall of an opening in the second region,
wherein, when forming the word line pick-up structures, a portion of the second dielectric layers in the second region that is closest to the opening is converted into a third dielectric material different from the second dielectric material.

2. The method of claim 1, wherein forming the word line pick-up structures comprises:
forming the openings extending through the first dielectric layers and the remainders of the second dielectric layers in the second region of the stack structure at different depths;
forming an interconnect line at a bottom of each of the openings, wherein the interconnect lines are in contact with the conductive layers, respectively; and
forming contact structures in the openings in contact with the interconnect lines, respectively.

3. The method of claim 2, further comprising:
forming a filler in each of the openings after forming the respective contact structure.

4. The method of claim 2, wherein forming the word line pick-up structures further comprises:
creating recesses in at least some of the remainders of the second dielectric layers exposed after forming the openings; and
covering the recesses with the third dielectric material to form buffers.

5. The method of claim 4, further comprising:
after covering the recesses with the third dielectric material, covering the sidewalls of the openings with a fourth dielectric material to form contact spacers.

6. The method of claim 5, wherein the fourth dielectric material is the same as the third dielectric material.

7. The method of claim 2, wherein forming the word line pick-up structures further comprises:
oxidizing the remainders of the second dielectric layers to form buffers.

8. The method of claim 7, wherein the buffers are formed by one of thermal oxidation or wet chemical oxidation.

9. The method of claim 4, wherein forming the word line pick-up structures further comprises:
etching the bottom of each of the openings to expose part of the second dielectric layer, respectively; and
removing a respective portion of the exposed second dielectric layer in each of the openings before forming the interconnect line in the removed portion, respectively.

10. A three-dimensional (3D) memory device, comprising:
a first region of a stack structure, the first region comprising interleaved conductive layers and first dielectric layers;
a second region of the stack structure, the second region comprising interleaved second dielectric layers and the first dielectric layers; and
word line pick-up structures, each extending along a sidewall of an opening into the second region of the stack structure,
wherein a buffer covering the sidewall is disposed between the second dielectric layers and the word line pick-up structure, and
wherein a surface of the buffer has a plurality of bumps along a direction parallel to the sidewall.

11. The 3D memory device of claim 10, wherein a contact spacer is formed between the buffer and the word line pick-up structures.

12. The 3D memory device of claim 11, wherein the contact spacer and the buffer each comprise a dielectric material selected from a group consisting of silicon oxide, silicon oxynitride, and a mixture of silicon oxide and silicon oxynitride.

13. The 3D memory device of claim 10, wherein each of the word line pick-up structures comprises:
an interconnect line at a bottom of the word line pick-up structure, wherein the interconnect line is in contact with one of the conductive layers;
a contact structure electrically coupled to the interconnect line; and
a filler that fills a remaining portion of the opening.

14. The 3D memory device of claim 10, wherein each of the plurality of bumps laterally corresponds to one of the first dielectric layers in the second region of the stack structure.

15. The 3D memory device of claim 10, wherein each of the plurality of bumps laterally corresponds to one of the second dielectric layers in the second region of the stack structure.

16. The 3D memory device of claim 15, wherein the thickness of dielectric layers near the bottom of the word line pick-up structure is smaller than that of dielectric layers near the top of the bottom of the word line pick-up structure.

17. The 3D memory device of claim 15, wherein the dielectric material comprises a native oxide layer.

18. The 3D memory device of claim 10, wherein the sidewall of at least one of the openings has a sidewall shoulder.

19. The 3D memory device of claim 10, wherein the word line pick-up structures extend into the second region of the stack structure at different depths.

20. A system, comprising:
a three-dimensional (3D) memory device configured to store data, the 3D memory device comprising:
a first region of a stack structure, the first region comprising interleaved conductive layers and first dielectric layers;
a second region of the stack structure, the second region comprising interleaved second dielectric layers and the first dielectric layers; and
word line pick-up structures, each extending along a sidewall of an opening into the second region of the stack structure,
wherein a buffer covering the sidewall is disposed between the second dielectric layers and the word line pick-up structure, and
wherein a surface of the buffer has a plurality of bumps along a direction parallel to the sidewall; and
a memory controller coupled to the 3D memory device and configured to control the 3D memory device.
